(19) United States
(12) Patent Application Publication
(10) Pub. No.: US 2020/0235100 A1
(43) Pub. Date: Jul. 23, 2020

(54) TRANSISTOR INCLUDING OXIDE SEMICONDUCTOR

(71) Applicant: Semiconductor Energy Laboratory Co., Ltd., Atsugi-shi, Kanagawa-ken (JP)

(72) Inventors: Shunpei YAMAZAKI, Setagaya (JP); Tomonori NAKAYAMA, Atsugi (JP); Haruyuki BABA, Isehara (JP)

(73) Assignee: Semiconductor Energy Laboratory Co., Ltd., Atsugi-shi, Kanagawa-ken (JP)

(21) Appl. No.: 16/652,808

(22) PCT Filed: Nov. 15, 2018
(86) PCT No.: PCT/IB2018/058984

§ 371 Date: Apr. 1, 2020

(30) Foreign Application Priority Data
Nov. 24, 2017 (JP) 2017-225437
Feb. 19, 2018 (JP) 2018-027169

(51) Int. Cl. H01L 27/108; H01L 29/792; H01L 29/51; H01L 29/786; H01L 27/088

(52) U.S. Cl. CPC H01L 27/108; H01L 29/792; H01L 27/088; H01L 29/786; H01L 29/517

(57) ABSTRACT

A semiconductor device having high frequency characteristics and high reliability is provided. Part of metal elements included in the oxide semiconductor including indium is replaced with cerium (Ce). When indium (In) included in the oxide semiconductor is replaced with cerium, electrons serving as carriers are released. Thus, by adjusting the ratio of cerium included in the oxide semiconductor, the carrier density of the oxide semiconductor can be controlled. In the case where the transistor is used for a memory element or the like, a cerium atom may be greater than or equal to 0.01 atomic % and less than or equal to 1.0 atomic % of metal atoms included in the oxide semiconductor.

### TECHNICAL FIELD

One embodiment of the present invention relates to a transistor, a semiconductor device, and a method for driving the semiconductor device. Alternatively, one embodiment of the present invention relates to an electronic device.

In this specification and the like, a semiconductor device generally means a device that can function by utilizing semiconductor characteristics. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

### BACKGROUND ART

A technique in which a transistor is formed using a semiconductor thin film has attracted attention. The transistor is widely applied to electronic devices such as an integrated circuit (IC) and an image display device (also simply referred to as a display device). A widely known semiconductor thin film that can be used for the transistor is a silicon-based semiconductor material; an oxide semiconductor has attracted attention as another material.

As the oxide semiconductor, not only single-component metal oxides, such as indium oxide and zinc oxide, but also multi-component metal oxides are known. Among the multi-component metal oxides, in particular, an In—Ga—Zn oxide (hereinafter also referred to as IGZO) has been actively studied.

From the studies on IGZO, a CAAC (c-axis aligned crystalline) structure and an nc (nanocrystalline) structure, which are not single crystal nor amorphous, have been found in an oxide semiconductor (see Non-Patent Document 1 to Non-Patent Document 3). In Non-Patent Document 1 and Non-Patent Document 2, a technique for fabricating a transistor using an oxide semiconductor having a CAAC structure is also disclosed. Moreover, Non-Patent Document 4 and Non-Patent Document 5 show that a fine crystal is included even in an oxide semiconductor which has lower crystallinity than an oxide semiconductor having the CAAC structure or the nc structure.

In addition, a transistor using IGZO for an active layer has an extremely low off-state current (see Non-Patent Document 6), and an LSI and a display utilizing the characteristics have been reported (see Non-Patent Document 7 and Non-Patent Document 8).

Furthermore, hydrogenated indium oxide to which cerium is added has been reported for a transparent conductive film used for a solar cell or the like (see Non-Patent Document 9).

### REFERENCES

### Non-Patent Documents

[Non-Patent Document 1] S. Yamazaki et al., “SID Symposium Digest of Technical Papers”, 2012, volume 43, issue 1, pp. 183-186.
[Non-Patent Document 2] S. Yamazaki et al., “Japanese Journal of Applied Physics”, 2014, volume 53, Number 4S, pp. 04ED18-1-04ED18-10.
[Non-Patent Document 3] S. Ito et al., “The Proceedings of AM-FPD'13 Digest of Technical Papers”, 2013, pp. 151-154.
[Non-Patent Document 4] S. Yamazaki et al., “ECS Journal of Solid State Science and Technology”, 2014, volume 3, issue 9, pp. Q3012-Q3022.
[Non-Patent Document 5] S. Yamazaki, “ECS Transactions”, 2014, volume 64, issue 10, pp. 155-164.
[Non-Patent Document 6] K. Kato et al., “Japanese Journal of Applied Physics”, 2012, volume 51, pp. 021201-1-021201-7.
[Non-Patent Document 7] S. Matsuda et al., “2015 Symposium on VLSI Technology Digest of Technical Papers”, 2015, pp. T216-T217.
[Non-Patent Document 8] S. Amano et al., “SID Symposium Digest of Technical Papers”, 2010, volume 41, issue 1, pp. 626-629.
[Non-Patent Document 9] E. Kobayashi et al., “Applied Physics Express”, 2015, volume 8, pp. 015505-1-015505-3

### SUMMARY OF THE INVENTION

### Problems to be Solved by the Invention

Non-Patent Document 9 discloses a metal oxide including cerium as a conductor. On the other hand, a structure where a metal oxide is used for a semiconductor layer of a transistor is not disclosed or suggested. An object of one embodiment of the present invention is to provide a novel oxide semiconductor.

An object of one embodiment of the present invention is to provide a semiconductor device with favorable electrical characteristics. An object of one embodiment of the present invention is to provide a semiconductor device with high reliability. An object of one embodiment of the present invention is to provide a semiconductor device that can be miniaturized or highly integrated. An object of one embodiment of the present invention is to provide a semiconductor device with high productivity.

Another object of one embodiment of the present invention is to provide a semiconductor device that can retain data for a long time. An object of one embodiment of the present invention is to provide a semiconductor device capable of high-speed data writing. An object of one embodiment of the present invention is to provide a semiconductor device with high design flexibility. An object of one embodiment of the present invention is to provide a semiconductor device with low power consumption. An object of one embodiment of the present invention is to provide a novel semiconductor device.

Note that the descriptions of these objects do not disturb the existence of other objects. One embodiment of the present invention does not have to achieve all the objects. Other objects are apparent from and can be derived from the description of the specification, the drawings, the claims, and the like.

### Means for Solving the Problems

One embodiment of the present invention is a transistor including a conductor, an oxide semiconductor, and an insulator positioned between the conductor and the oxide semiconductor, and the oxide semiconductor includes indium, zinc, and a metal element M (M is one or more of metal elements selected from cerium, tungsten, and molybdenum).

One embodiment of the present invention is a transistor including a conductor, an oxide semiconductor, and an insulator positioned between the conductor and the oxide semiconductor, and the oxide semiconductor includes indium, zinc, gallium, and a metal element M (M is one or more of metal elements selected from cerium, tungsten, and molybdenum).

In the above structure, the metal element M is greater than or equal to 0.01 atomic % and less than or equal to 1.0 atomic % of metal atoms included in the oxide semiconductor.

In the above structure, the metal element M is cerium.

In the above structure, the oxide semiconductor includes a CAAC-OS.

In the above structure, the oxide semiconductor includes an nc-OS.

One embodiment of the present invention is a transistor including a first oxide, a second oxide, a third oxide, a first conductor, a second conductor, a third conductor, and an insulator; the first oxide includes a first region, a second region, and a third region; the first region includes a region overlapping with the first conductor with the insulator therebetween; the second region overlaps with the second conductor with the second oxide therebetween; the third region overlaps with the third conductor with the third oxide therebetween; and the second oxide and the third oxide have higher cerium contents than the first oxide.

### Effect of the Invention

According to one embodiment of the present invention, a transistor includes an oxide semiconductor with stable electrical characteristics and high reliability. Furthermore, a semiconductor device including the transistor has high reliability.

According to one embodiment of the present invention, a semiconductor device having favorable electrical characteristics can be provided. According to one embodiment of the present invention, a highly reliable semiconductor device can be provided. According to one embodiment of the present invention, a semiconductor device that can be miniaturized or highly integrated can be provided. According to one embodiment of the present invention, a semiconductor device with high productivity can be provided.

According to one embodiment of the present invention, a semiconductor device that can retain data for a long time can be provided. According to one embodiment of the present invention, a semiconductor device capable of high-speed data writing can be provided. According to one embodiment of the present invention, a semiconductor device with high design flexibility can be provided. According to one embodiment of the present invention, a semiconductor device whose power consumption can be reduced can be provided. According to one embodiment of the present invention, a novel semiconductor device can be provided.

Note that the descriptions of the effects do not disturb the existence of other effects. One embodiment of the present invention does not have to have all of these effects. Other effects are apparent from and can be derived from the description of the specification, the drawings, the claims, and the like.

### BRIEF DESCRIPTION OF THE DRAWINGS

FIG. 1 A schematic view of a transistor of one embodiment of the present invention and a figure illustrating a model of an oxide semiconductor.

FIG. 2 A top view and cross-sectional views of a semiconductor device of one embodiment of the present invention.

FIG. 3 A top view and cross-sectional views of a semiconductor device of one embodiment of the present invention.

FIG. 4 A top view and cross-sectional views of a semiconductor device of one embodiment of the present invention.

FIG. 5 A top view and cross-sectional views of a semiconductor device of one embodiment of the present invention.

FIG. 6 A cross sectional view illustrating a structure of a memory device of one embodiment of the present invention.

FIG. 7 A cross-sectional view illustrating a structure of a memory device of one embodiment of the present invention.

FIG. 8 Block diagrams illustrating a configuration example of a memory device of one embodiment of the present invention.

FIG. 9 Circuit diagrams illustrating configuration examples of a memory device of one embodiment of the present invention.

FIG. 10 Schematic views of a memory device of one embodiment of the present invention.

FIG. 11 Schematic views of memory devices of one embodiment of the present invention.

### MODE FOR CARRYING OUT THE INVENTION

Hereinafter, embodiments are described with reference to drawings. Note that the embodiments can be implemented with many different modes, and it is readily appreciated by those skilled in the art that modes and details can be changed in various ways without departing from the spirit and scope of the present invention. Thus, the present invention should not be interpreted as being limited to the following description of the embodiments.

In the drawings, the size, the layer thickness, or the region is exaggerated for clarity in some cases. Therefore, the size, the layer thickness, or the region is not limited to the illustrated scale. The drawings are schematic views showing ideal examples, and embodiments of the present invention are not limited to shapes or values shown in the drawings. In the drawings, the same portions or portions having similar functions are denoted by the same reference numerals in different drawings, and explanation thereof is not repeated. Furthermore, the same hatch pattern is used for the portions having similar functions, and the portions are not especially denoted by reference numerals in some cases.

In this specification, terms for describing arrangement, such as “over” and “under”, are used for convenience in describing a positional relation between components with reference to drawings. Furthermore, the positional relation between components is changed as appropriate in accordance with a direction in which each component is described. Thus, terms for the description are not limited to those used in this specification, and the description can be rephrased appropriately depending on the situation.

In this specification and the like, a transistor is an element having at least three terminals of a gate, a drain, and a source. The transistor has a channel formation region between the drain (a drain terminal, a drain region, or a drain electrode) and the source (a source terminal, a source region, or a source electrode), and current can flow through the drain, the channel formation region, and the source. Note that in this specification and the like, a channel formation region refers to a region through which current mainly flows.

Furthermore, functions of a source and a drain might be switched when a transistor of opposite polarity is employed or a direction of current is changed in circuit operation, for example. Therefore, the terms “source” and “drain” are used interchangeably in this specification and the like.

Furthermore, in this specification and the like, “electrically connected” includes the case where connection is made through an “object having any electric function”. Here, there is no particular limitation on the “object having any electric function” as long as electric signals can be transmitted and received between the connected components. Examples of the “object having any electric function” include a switching element such as a transistor, a resistor, an inductor, a capacitor, and other elements with a variety of functions as well as an electrode and a wiring.

Note that in this specification and the like, a nitride oxide refers to a compound that includes more nitrogen than oxygen. An oxynitride refers to a compound that includes more oxygen than nitrogen. The content of each element can be measured by Rutherford backscattering spectrometry (RBS), for example.

In this specification and the like, “parallel” indicates a state where two straight lines are placed at an angle of greater than or equal to −10° and less than or equal to 10°. Thus, the case where the angle is greater than or equal to −5° and less than or equal to 5° is also included. In addition, the term “substantially parallel” indicates a state where two straight lines are placed at an angle of greater than or equal to −30° and less than or equal to 30°. Moreover, “perpendicular” indicates a state where two straight lines are placed at an angle of greater than or equal to 80° and less than or equal to 100°. Thus, the case where the angle is greater than or equal to 85° and less than or equal to 95° is also included. Furthermore, “substantially perpendicular” indicates a state where two straight lines are placed at an angle of greater than or equal to 60° and less than or equal to 120°.

Note that in this specification, a barrier film means a film having a function of inhibiting the passage of oxygen and impurities such as hydrogen, and the barrier film having conductivity is referred to as a conductive barrier film in some cases.

In this specification and the like, a transistor having normally-on characteristics is a transistor that is on when no potential (0 V) is applied by a power source. For example, the normally-on characteristics of a transistor mean, in some cases, electrical characteristics in which current (Id) flows between a drain and a source when a voltage applied to a gate of the transistor (Vg) is 0 V.

In this specification and the like, an oxide semiconductor is a type of metal oxide. A metal oxide means an oxide including a metal element. A metal oxide exhibits insulating properties, semiconductor properties, or conductivities depending on its composition or formation method. A metal oxide exhibiting semiconductor properties is referred to as a metal oxide semiconductor or an oxide semiconductor (or simply OS). A metal oxide exhibiting insulating properties is referred to as a metal oxide insulator or an oxide insulator. A metal oxide exhibiting conductivities is referred to as a metal oxide conductor or an oxide conductor. In other words, a metal oxide used in a channel formation region or the like of a transistor can be referred to as an oxide semiconductor.

Note that oxide semiconductors are classified into a single crystal oxide semiconductor and a non-single-crystal oxide semiconductor. Examples of a non-single-crystal oxide semiconductor include a polycrystalline oxide semiconductor and an amorphous oxide semiconductor.

As an oxide semiconductor used for a semiconductor of the transistor, a thin film having high crystallinity is preferably used. With the use of the thin film, the stability or the reliability of the transistor can be improved. Examples of the thin film include a thin film of a single-crystal oxide semiconductor and a thin film of a polycrystalline oxide semiconductor. However, for forming the thin film of a single-crystal oxide semiconductor or the thin film of a polycrystalline oxide semiconductor over a substrate, a high-temperature process or a laser heating process is needed. Thus, the manufacturing cost is increased, and in addition, the throughput is decreased.

Non-Patent Document 1 and Non-Patent Document 2 have reported that an In—Ga—Zn oxide having a CAAC structure (referred to as CAAC-IGZO) was found in 2009. It has been reported that CAAC-IGZO has c-axis alignment, a crystal grain boundary is not clearly observed in CAAC-IGZO, and CAAC-IGZO can be formed over a substrate at low temperatures. It has also been reported that a transistor using CAAC-IGZO has excellent electrical characteristics and high reliability.

In addition, in 2013, an In—Ga—Zn oxide having an nc structure (referred to as nc-IGZO) was found (see Non-Patent Document 3). It has been reported that nc-IGZO has periodic atomic arrangement in a microscopic region (for example, a region with a size greater than or equal to 1 nm and less than or equal to 3 nm) and there is no regularity of crystal orientation between different regions.

Non-Patent Document 4 and Non-Patent Document 5 have shown a change in average crystal size due to electron beam irradiation to thin films of the above CAAC-IGZO, the above nc-IGZO, and IGZO having low crystallinity. In the thin film of IGZO having low crystallinity, crystalline IGZO with a crystal size of approximately 1 nm was observed even before the electron beam irradiation. Thus, it has been reported that the existence of a completely amorphous structure was not observed in IGZO. In addition, it has been shown that the thin film of CAAC-IGZO and the thin film of nc-IGZO each have higher stability to electron beam irradiation than the thin film of IGZO having low crystallinity. Thus, the thin film of CAAC-IGZO or the thin film of nc-IGZO is preferably used for a semiconductor of a transistor.

Non-Patent Document 6 shows that a transistor using an oxide semiconductor has an extremely low leakage current in a non-conduction state; specifically, the off-state current per micrometer in the channel width of the transistor is of the order of yA/μm (10⁻²⁴ A/μm). For example, a low-power-consumption CPU utilizing a characteristic of a low leakage current of the transistor using an oxide semiconductor is disclosed (see Non-Patent Document 7).

Furthermore, application of a transistor using an oxide semiconductor to a display device that utilizes the characteristic of a low leakage current of the transistor has been reported (see Non-Patent Document 8). In the display device, a displayed image is changed several tens of times per second. The number of times an image is changed per second is referred to as a refresh rate. The refresh rate is also referred to as driving frequency. Such high-speed screen change that is hard for human eyes to recognize is considered as a cause of eyestrain. Thus, it is proposed that the refresh rate of the display device is lowered to reduce the number of times of image rewriting. Moreover, driving with a lowered refresh rate enables the power consumption of the display device to be reduced. Such a driving method is referred to as idling stop (IDS) driving.

The discovery of the CAAC structure and the nc structure has contributed to an improvement in electrical characteristics and reliability of a transistor using an oxide semiconductor having the CAAC structure or the nc structure, a reduction in manufacturing cost, and an improvement in throughput. Furthermore, applications of the transistor to a display device and an LSI utilizing the characteristics of a low leakage current of the transistor have been studied.

### Embodiment 1

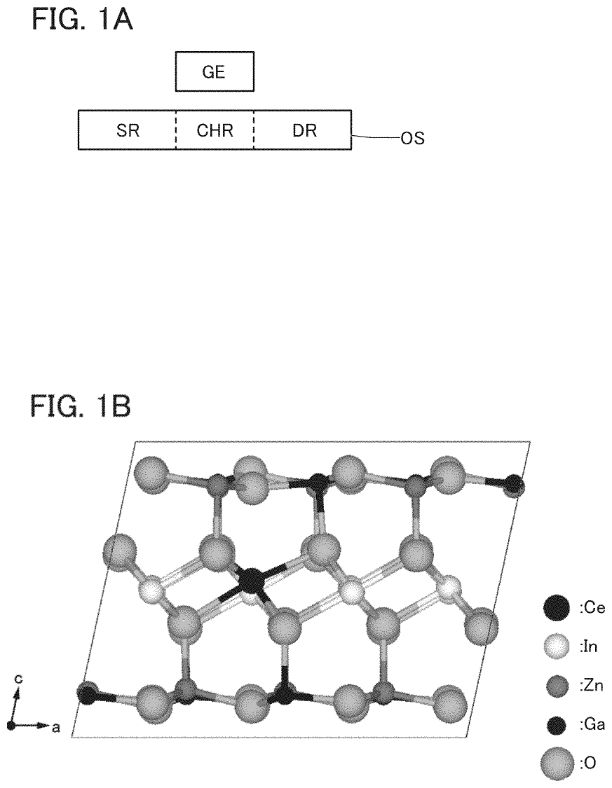

In this embodiment, a transistor using an oxide semiconductor of one embodiment of the present invention is described with reference to FIG. 1.

### <Structure Example of Transistor>

FIG. 1(A) is a schematic view of a transistor 200 of one embodiment of the present invention. For clarity of the drawing, some components are not illustrated in FIG. 1(A).

### [Transistor 200]

As illustrated in FIG. 1(A), the transistor 200 includes at least GE functioning as a gate, and an oxide semiconductor OS including a region CHR where a channel is formed (hereinafter also referred to as a channel formation region). The oxide semiconductor OS includes a region SR functioning as a source and a region DR functioning as a drain.

The transistor 200 using an oxide semiconductor in the region CHR where the channel is formed has an extremely low leakage current in a non-conduction state; thus, a semiconductor device with low power consumption can be provided. An oxide semiconductor can be deposited by a sputtering method or the like, and thus can be used for the transistor 200 constituting a highly integrated semiconductor device.

For example, a metal oxide including indium is preferably used as the oxide semiconductor OS. For example, a metal oxide such as an In-M1-Zn oxide (the element M1 is one or more of aluminum, gallium, yttrium, copper, vanadium, beryllium, boron, titanium, iron, nickel, germanium, zirconium, molybdenum, lanthanum, hafnium, tantalum, tungsten, magnesium, and the like) can be used. Furthermore, as the oxide semiconductor OS, an In—Ga oxide or an In—Zn oxide may be used.

One embodiment of the present invention is a semiconductor in which part of metal elements included in the oxide semiconductor are replaced with metal elements M2 whose oxidation number is larger than the oxidation number of the metal element. Thus, the oxide semiconductor of one embodiment of the present invention includes one or more elements selected from the metal elements M2 in addition to indium (In), the element M1, and zinc (Zn) which are described above.

As the metal element M2, lanthanoid that can have a valence of +4, which is typified by cerium (Ce) that can be replaced with indium that has a valence of +3, can be given. Furthermore, as the metal element M2 that can be replaced with zinc that has a valence of +2, tungsten (W), molybdenum (Mo), and the like can be given. Note that in the oxide semiconductor, the oxidation number of tungsten can have a valence of +6 and the oxidation number of molybdenum can have a valence of +6.

In addition, as the lanthanoid that can have a valence of +4, specifically, cerium (Ce), praseodymium (Pr), neodymium (Nd), terbium (Tb), dysprosium (Dy), and the like can be given. In particular, among the lanthanoid that can have a valence of +4, cerium stably has a valence of +4, which is preferable. In addition, the abundance of cerium is high among rare earth elements, and thus cerium is supposed to be provided stably, and an increase in cost can be suppressed. As an example, FIG. 1(B) specifically illustrates an atomic arrangement of an oxide semiconductor in which indium is replaced with cerium.

Table 1 shows the ion radius of indium, zinc, gallium, which is an example of the element M1, and typical metal elements M2 and the bond energy between an oxygen atom and each metal atom.

TABLE 1

| | Ion radius | Bond energy with oxygen atom |
|---|---|---|
| Metal atom | [nm] | [eV] |
| In | 0.96 × 10⁻¹ | 1.83 |
| Ga | 0.55 × 10⁻¹ | 2.99 |
| Zn | 0.68 × 10⁻¹ | 1.74 |
| W | 0.59 × 10⁻¹~0.65 × 10⁻¹ | 3.38~4.37 |
| Mo | 0.6 × 10⁻¹~0.66 × 10⁻¹ | 3.05~3.87 |
| Ce | 0.97 × 10⁻¹ | 3.50 |

As shown in Table 1, the ion radius of cerium is an approximate value of the ion radius of indium. Thus, it is highly possible that cerium in the oxide semiconductor is replaced with indium in particular. On the other hand, the ion radii of tungsten and molybdenum are approximate values of the ion radius of zinc. Thus, it is highly possible that tungsten and molybdenum are replaced with zinc in particular.

Hereinafter, an oxide semiconductor in which part of indium (In) that is mainly included in the oxide semiconductor is replaced with cerium as illustrated in FIG. 1(B) is described as an example. However, cerium is sometimes replaced with the metal element M1 or zinc that is included in the oxide semiconductor. Similarly, even in the case of an oxide semiconductor in which zinc that is mainly included in the oxide semiconductor is replaced with tungsten, molybdenum, or the like, tungsten, molybdenum, or the like may also be replaced with indium or the metal element M1.

Here, indium (In), which is a metal element included in an oxide semiconductor, has a valence of +3. When indium in the oxide semiconductor OS is replaced with cerium, electrons serving as carriers are released. That is to say, one indium having a valence of +3 is replaced with one cerium, whereby one electron is generated.

Thus, by adjusting the ratio of cerium included in the oxide semiconductor, the carrier density of the oxide semiconductor can be controlled. That is, the ratio of cerium is preferably adjusted as appropriate in accordance with the design of the transistor. Accordingly, with the use of the oxide semiconductor including cerium as the oxide semiconductor OS in the transistor 200, a transistor with high mobility and high frequency characteristics can be provided.

Specifically, in the case where the transistor 200 is used for a memory element or the like, a lanthanoid atom having a valence of +4 is set to greater than or equal to 0.01 atomic % and less than or equal to 1.0 atomic % of metal atoms included in the oxide semiconductor.

Hereinafter, the case where the above oxide semiconductor is used for the transistor 200 is described.

For example, when the above oxide semiconductor is used in the region CHR where the channel is formed of the transistor 200, the transistor having high field-effect mobility can be achieved. In addition, the transistor having high reliability can be achieved.

When the oxide semiconductor is used for the region CHR where the channel is formed, the impurity concentration and the density of defect states in the oxide semiconductor are preferably reduced. Note that in this specification and the like, a state with a low impurity concentration and a low density of defect states is referred to as a highly purified intrinsic or substantially highly purified intrinsic state.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and may behave like fixed charge. Thus, the use of an oxide semiconductor with a high density of trap states for the region CHR where the channel is formed makes the electrical characteristics unstable in some cases.

Impurities such as hydrogen included in the oxide semiconductor reacts with oxygen bonded to a metal atom to be water, and thus an oxygen vacancy (Vo) is formed in some cases. A transistor using an oxide semiconductor is likely to have its electrical characteristics changed by impurities and oxygen vacancies in the oxide semiconductor, which might affect the reliability. In particular, if the region CHR where the channel is formed of the oxide semiconductor OS includes oxygen vacancies, the transistor tends to have normally-on characteristics.

Thus, oxygen vacancies in the region CHR where the channel is formed are preferably reduced as much as possible. When an oxide semiconductor with reduced oxygen vacancies is used for a channel formation region of a transistor, stable electrical characteristics can be given.

Here, in the case where part of indium included in the oxide semiconductor is replaced with cerium, as shown in Table 1, the bond energy between a cerium atom and an oxygen atom is higher than the bond energy between an indium atom and an oxygen atom. Accordingly, even when impurities such as hydrogen are close to an oxygen atom bonded to a cerium atom, the impurities are unlikely to react with the oxygen atom. That is, formation of oxygen vacancies is suppressed in an oxide semiconductor including cerium, so that a highly purified intrinsic oxide semiconductor can be easily formed.

Note that an oxide including oxygen more than oxygen in the stoichiometric composition is placed near the oxide semiconductor; thus, oxygen vacancies in the oxide semiconductor can be reduced. For example, an insulating oxide is preferably used as an insulator in contact with the oxide semiconductor, and a region including oxygen in excess of oxygen in the stoichiometric composition (hereinafter also referred to as an excess oxygen region) is preferably provided in the insulating oxide. The excess oxygen is diffused into the oxide semiconductor, whereby oxygen vacancies can be filled.

An oxide semiconductor is classified into a single crystal oxide semiconductor and a non-single crystal oxide semiconductor. Examples of a non-single-crystal oxide semiconductor include CAAC-OS (a c-axis aligned crystalline oxide semiconductor), a polycrystalline oxide semiconductor, an nc-OS (nanocrystalline oxide semiconductor), and an amorphous-like oxide semiconductor (a-like OS).

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected. The nanocrystal is basically a hexagon but is not always a regular hexagon and is a non-regular hexagon in some cases. Furthermore, a pentagonal or heptagonal lattice arrangement, for example, is included in the distortion in some cases.

Note that it is difficult to observe a clear crystal grain boundary (also referred to as grain boundary) even in the vicinity of distortion in the CAAC-OS. That is, formation of a crystal grain boundary is inhibited by the distortion of a lattice arrangement. This is because the CAAC-OS can tolerate distortion owing to a low density of arrangement of oxygen atoms in the a-b plane direction, an interatomic bond length changed by substitution of a metal element, and the like.

Furthermore, the CAAC-OS tends to have a layered crystal structure (also referred to as a layered structure) in which a layer including indium and oxygen (hereinafter, In layer) and a layer including the element M1, zinc, and oxygen (hereinafter, (M,Zn) layer) are stacked. Note that indium and the element M1 can be replaced with each other, and when the element M1 in the (M,Zn) layer is replaced with indium, the layer can also be referred to as an (In,M,Zn) layer. Furthermore, when indium in the In layer is replaced with the element M1, the layer can be referred to as an (In,M) layer.

Here, one embodiment of the present invention is an oxide semiconductor in which indium, which is a metal element included in the oxide semiconductor, is replaced with cerium. As shown in Table 1, the ion radius of indium and the ion radius of cerium are substantially equal; thus, indium in the In layer or the (In, M, Zn) layer is replaced with cerium while the layered crystal structure is kept (see FIG. 1(B)). That is, the oxide semiconductor in which part of indium is replaced with cerium can form a CAAC-OS.

The CAAC-OS is an oxide semiconductor with high crystallinity. By contrast, in the CAAC-OS, a reduction in electron mobility due to the crystal grain boundary is less likely to occur because it is difficult to observe a clear crystal grain boundary. Moreover, since the crystallinity of an oxide semiconductor might be decreased by entry of impurities, formation of defects, or the like, the CAAC-OS can be regarded as an oxide semiconductor that has small amounts of impurities and defects (oxygen vacancies or the like). Thus, an oxide semiconductor including a CAAC-OS is physically stable. Therefore, the oxide semiconductor including a CAAC-OS is resistant to heat and has high reliability.

Note that in the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, in some cases, the nc-OS cannot be distinguished from an a-like OS or an amorphous oxide, depending on an analysis method.

The a-like OS is an oxide semiconductor having lower crystallinity than the CAAC-OS and the nc-OS. The a-like OS includes a void or a low-density region.

Two or more of the polycrystalline oxide semiconductor, the a-like OS, the nc-OS, and the CAAC-OS may be included in an oxide semiconductor including lanthanoid having a valence of +4.

Note that in the case where the oxide semiconductor including cerium is used as the oxide semiconductor OS of the transistor 200, the oxide semiconductor OS preferably includes a region with a CAAC-OS structure. In particular, in the oxide semiconductor OS, the region CHR where the channel is formed preferably has a CAAC-OS structure.

In contrast, the oxide semiconductor may be used for the region SR functioning as the source of the transistor 200 and the region DR functioning as the drain of the transistor 200. For example, the lanthanoid having a valence of +4 in the oxide semiconductor functions as an electron donor (also referred to as a donor). When the oxide semiconductor is used for the region SR functioning as the source and the region DR functioning as the drain, a transistor with high field-effect mobility can be achieved.

Thus, by appropriate adjustment of the rate of cerium added to the oxide semiconductor, a transistor having electrical characteristics that meet the demand for the circuit design can be easily provided.

Furthermore, a semiconductor device including a transistor having a high on-state current can be provided. Alternatively, a semiconductor device including a transistor having a low off-state current can be provided. Alternatively, a semiconductor device that has small variation in electrical characteristics, stable electrical characteristics, and high reliability can be provided. An oxide semiconductor can be deposited by a sputtering method or the like, and thus can be used for a transistor constituting a highly integrated semiconductor device.

The composition, structure, method, and the like described above in this embodiment can be used in combination as appropriate with the compositions, structures, methods, and the like described in the other embodiments.

### Embodiment 2

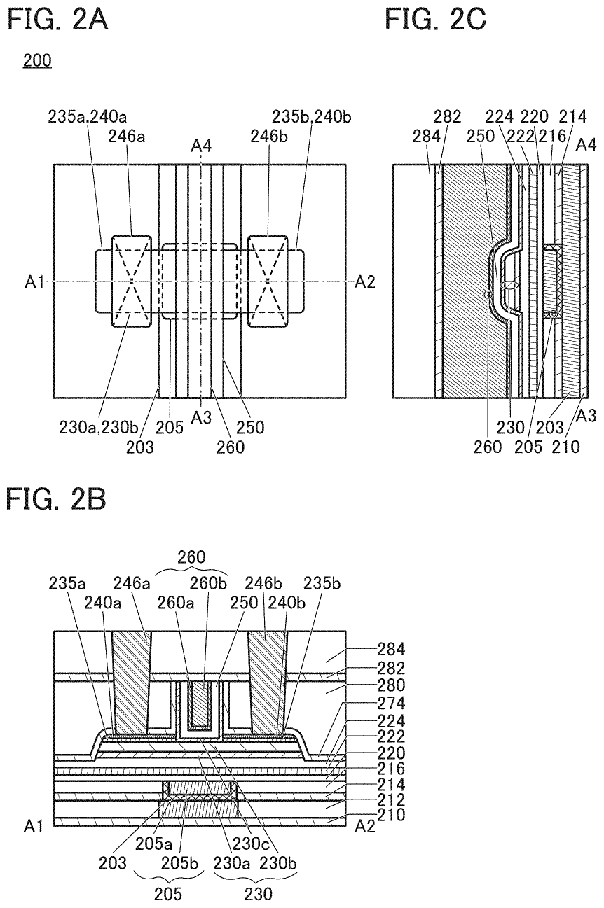

In this embodiment, embodiments of semiconductor devices are described with reference to FIG. 2 to FIG. 4.

### <Structure 1 of Semiconductor Device>

An example of a semiconductor device including the transistor 200 of one embodiment of the present invention is described below. FIG. 2(A), FIG. 2(B), and FIG. 2(C) are a top view and cross-sectional views of a transistor 200 of one embodiment of the present invention and a periphery of the transistor 200. FIG. 2(A) is a top view, FIG. 2(B) is a cross-sectional view corresponding to dashed-dotted line A1-A2 in FIG. 2(A), and FIG. 2(C) is a cross-sectional view corresponding to dashed-dotted line A3-A4 in FIG. 2(A). Note that for simplification of the drawing, some components are not illustrated in the top view in FIG. 2(A).

The semiconductor device of one embodiment of the present invention includes the transistor 200, and an insulator 210, an insulator 212, an insulator 214, an insulator 216, an insulator 280, an insulator 282, and an insulator 284 functioning as interlayer films.

The conductor 246 (the conductor 246a and the conductor 246b) functioning as a plug and being electrically connected to the transistor 200 is also included. The semiconductor device further includes a conductor 203 that is electrically connected to the transistor 200 and functions as a wiring.

The transistor 200 includes a conductor 260 (a conductor 260a and a conductor 260b) functioning as a first gate electrode, a conductor 205 (a conductor 205a and a conductor 205b) functioning as a second gate electrode, an insulator 250 functioning as a first gate insulating film, an insulator 220, an insulator 222, and an insulator 224 functioning as second gate insulating layers, an oxide 230 (an oxide 230a, an oxide 230b, and an oxide 230c) including a channel formation region, a conductor 240a functioning as one of a source and a drain, a conductor 240b functioning as the other of the source and the drain, an oxide 235 (an oxide 235a and an oxide 235b) provided between the oxide 230 and the conductor 240, and an insulator 274.

The oxide semiconductor described in Embodiment 1 can be used for the oxide 230 in the transistor 200. The use of the oxide semiconductor for the oxide 230 can suppress generation of oxygen vacancies in the oxide 230. Thus, the transistor having high reliability can be provided. Furthermore, the carrier concentration of the transistor can be adjusted, so that the degree of freedom in design is improved. An oxide semiconductor can be deposited by a sputtering method or the like, and thus can be used for a transistor constituting a highly integrated semiconductor device.

The transistor illustrated in FIG. 2 includes the oxide 235 between the oxide 230 and the conductor 240. The oxide semiconductor in Embodiment 1 may be used for the oxide 235. In the case where an oxide semiconductor including lanthanoid having a valence of +4 is used for the oxide 235, the content of the lanthanoid having a valence of +4 of the oxide 235 is preferably higher than that of the oxide 230. When the content of the lanthanoid having a valence of +4 is high, the lanthanoid having a valence of +4 functions as an electron donor (donor). The provision of the oxide 235 can reduce the contact resistance between the conductor 240 and the oxide 230. Note that in this structure, when the oxide 235 functions as an electron donor, the oxide 235 is sometimes referred to as a conductive oxide.

In the transistor structure illustrated in FIG. 2, the oxide 230c, the insulator 250, and the conductor 260 are provided in an opening provided in the insulator 280 with the insulator 274 therebetween. The oxide 230c, the insulator 250, and the conductor 260 are provided between the conductor 240a and the conductor 240b.

In order that the transistor structure illustrated in FIG. 2 is formed, first, an oxide film to be the oxide 230 and a conductive film to be the conductor 240 over the oxide film are formed. Parts of the oxide film and the conductive film are removed, so that a stacked-layer structure of the island-shaped oxide 230 and the island-shaped conductive films is formed. Next, a dummy gate is provided over the stacked-layer structure. Note that a dummy gate is subjected to slimming processing or the like in a step of providing the dummy gate, so that miniaturization and high integration of the transistor can be achieved.

Next, an insulating film to be the insulator 274 is formed over the dummy gate, and over the insulating film, an insulating film to be the insulator 280 is formed. Then, part of the insulating film to be the insulator 274 and part of the insulating film to be the insulator 280 are removed by a chemical mechanical polishing (CMP) method or the like until the dummy gate is exposed. Then, the dummy gate is removed, so that an opening where the insulator 274, the top surface and side surfaces of the oxide 230a, the top surface and side surfaces of the oxide 230b, the side surface of the conductor 240a, and the side surface of the conductor 240b are exposed is formed. The oxide 230c, the insulator 250, and the conductor 260 are provided in the opening. Thus, the oxide 230c can be formed in the opening provided in the insulator 280 without being in contact with the insulator 280.

The structure of the semiconductor device including the transistor 200 of one embodiment of the present invention is described in detail below.

The insulator 210 and the insulator 212 function as interlayer films.

As the interlayer film, a single layer or a stacked layer of any of insulators such as silicon oxide, silicon oxynitride, silicon nitride oxide, aluminum oxide, hafnium oxide, tantalum oxide, zirconium oxide, lead zirconate titanate (PZT), strontium titanate (SrTiO₃), and (Ba,Sr)TiO₃ (BST) can be used. Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. Silicon oxide, silicon oxynitride, or silicon nitride may be stacked over the insulators.

For example, the insulator 210 preferably functions as a barrier film that prevents impurities such as water or hydrogen from entering the transistor 200 from the substrate side. Accordingly, for the insulator 210, it is preferable to use an insulating material that has a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (that does not easily transmit the above impurities). Alternatively, it is preferable to use an insulating material which has a function of inhibiting diffusion of oxygen (e.g., at least one of oxygen atoms, oxygen molecules, and the like) (through which the above oxygen does not easily pass). Furthermore, for example, aluminum oxide or silicon nitride may be used for the insulator 210. With the structure, impurities such as hydrogen and water can be inhibited from being diffused from the side closer to the substrate than the insulator 210 to the transistor 200 side.

For example, the dielectric constant of the insulator 212 is preferably lower than that of the insulator 210. When a material with a low dielectric constant is used for an interlayer film, parasitic capacitance generated between wirings can be reduced.

Note that the conductor 203 is formed to be embedded in the insulator 212. The level of a top surface of the conductor 203 and the level of a top surface of the insulator 212 can be substantially the same. Note that although a structure where the conductor 203 is a single layer is illustrated, the present invention is not limited thereto. For example, the conductor 203 may have a multilayer structure of two or more layers. Note that in the case where a structure body has a stacked-layer structure, the layers may be distinguished by ordinal numbers corresponding to the formation order. Note that for the conductor 203, a conductive material with high conductivity that includes tungsten, copper, or aluminum as its main component is preferably used.

In the transistor 200, the conductor 260 sometimes functions as a first gate (also referred to as a top gate) electrode. The conductor 205 sometimes functions as a second gate (also referred to as a bottom gate) electrode. In that case, the threshold voltage of the transistor 200 can be controlled by changing a potential applied to the conductor 205 not in synchronization with but independently of a potential applied to the conductor 260. In particular, the threshold voltage of the transistor 200 can be higher than 0 V and the off-state current can be reduced by applying a negative potential to the conductor 205. Thus, a drain current when a potential applied to the conductor 260 is 0 V can be lower in the case where a negative potential is applied to the conductor 205 than in the case where the negative potential is not applied to the conductor 205.

Furthermore, for example, since the conductor 205 and the conductor 260 are provided to overlap with each other as illustrated in FIG. 2(A), when potentials are applied to the conductor 260 and the conductor 205, an electric field generated from the conductor 260 and an electric field generated from the conductor 205 are connected, so that the channel formation region formed in the oxide 230 can be covered.

That is, the channel formation region can be electrically surrounded by the electric field of the conductor 260 functioning as the first gate electrode and the electric field of the conductor 205 functioning as the second gate electrode. In this specification, a transistor structure where a channel formation region is electrically surrounded by electric fields of a first gate electrode and a second gate electrode is referred to as a surrounded channel (S-channel) structure.

Like the insulator 210 or the insulator 212, the insulator 214 and the insulator 216 function as interlayer films. For example, the insulator 214 preferably functions as a barrier film that prevents impurities such as water or hydrogen from entering the transistor 200 from the substrate side. With the structure, impurities such as hydrogen and water can be inhibited from being diffused to the transistor 200 side from the substrate side of the insulator 214. Furthermore, for example, the dielectric constant of the insulator 216 is preferably lower than that of the insulator 214. When a material with a low dielectric constant is used for an interlayer film, parasitic capacitance generated between wirings can be reduced.

In the conductor 205 functioning as a second gate, a first conductor is formed in contact with an inner wall of an opening in the insulator 214 and the insulator 216, and a second conductor is formed on the inner side. Here, the levels of top surfaces of the first conductor and the second conductor can be substantially the same as the level of a top surface of the insulator 216. Although the transistor 200 having a structure where the first conductor and the second conductor are stacked is described, the present invention is not limited thereto. For example, the conductor 205 may have a single-layer structure or a stacked-layer structure of three or more layers.

Here, for the conductor 205a, a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom (through which the above impurities are less likely to pass) is preferably used. Alternatively, it is preferable to use a conductive material that has a function of inhibiting diffusion of oxygen (e.g., at least one of oxygen atoms, oxygen molecules, and the like) (through which the above oxygen does not easily pass). Note that in this specification, a function of inhibiting diffusion of impurities or oxygen means a function of inhibiting diffusion of any one or all of the above impurities and the above oxygen.

When the conductor 205a has a function of inhibiting diffusion of oxygen, the conductivity of the conductor 205b can be prevented from being reduced because of oxidation.

In the case where the conductor 205 also functions as a wiring, a conductive material with high conductivity that includes tungsten, copper, or aluminum as its main component is preferably used for the conductor 205b. In that case, the conductor 203 is not necessarily provided. Note that the conductor 205b is illustrated as a single layer but may have a stacked-layer structure, for example, a stacked layer of any of the above conductive materials and titanium or titanium nitride.

The insulator 220, the insulator 222, and the insulator 224 each have a function of a second gate insulator.

For example, as the insulator 224 in contact with the oxide 230, an insulator including more oxygen than oxygen in the stoichiometric composition is preferably used. That is, an excess oxygen region is preferably formed in the insulator 224. When such an insulator including excess oxygen is provided in contact with the oxide 230, oxygen vacancies in the oxide 230 can be reduced, leading to an improvement in reliability of the transistor 200.

The insulator 222 preferably has a barrier property. The insulator 222 having a barrier property functions as a layer for suppressing the release of oxygen from the oxide 230 and entry of impurities such as hydrogen from the peripheral portion of the transistor 200 to the oxide 230. When the insulator 224 includes an excess oxygen region, oxygen in the excess oxygen region is not diffused to the insulator 220 side but can be supplied to the oxide 230 efficiently. Furthermore, the conductor 205 can be inhibited from reacting with oxygen from the excess oxygen region included in the insulator 224.

For the insulator 222, a single layer or stacked layers of an insulator including what is called a high-k material such as aluminum oxide, hafnium oxide, oxide including aluminum and hafnium (hafnium aluminate), tantalum oxide, zirconium oxide, lead zirconate titanate (PZT), strontium titanate (SrTiO₃), or (Ba,Sr)TiO₃ (BST) are preferably used, for example. With miniaturization and high integration of a transistor, a problem such as leakage current may arise because of a thinner gate insulator. When a high-k material is used for an insulator functioning as a gate insulator, a gate potential during operation of the transistor can be reduced while the physical thickness is kept.

For example, it is preferable that the insulator 220 be thermally stable. For example, silicon oxide and silicon oxynitride, which have thermal stability, are suitable. Furthermore, when an insulator which is a high-k material is combined with silicon oxide or silicon oxynitride, the insulator 220 having a stacked-layer structure that has thermal stability and a high dielectric constant can be obtained.

Note that although the second gate insulator has a three-layer structure in FIG. 2, a single-layer structure or a stacked-layer structure including two or more layers may be employed. In that case, without limitation to a stacked-layer structure formed of the same material, a stacked-layer structure formed of different materials may be employed.

The oxide 230 including a region functioning as a channel formation region includes the oxide 230a, the oxide 230b over the oxide 230a, and the oxide 230c over the oxide 230b. When the oxide 230a is provided below the oxide 230b, impurities can be prevented from being diffused into the oxide 230b from the components formed below the oxide 230a. When the oxide 230c is provided over the oxide 230b, impurities can be prevented from being diffused into the oxide 230b from the components formed above the oxide 230c.

Note that the oxide 230c is preferably provided in the opening in the insulator 280 with the insulator 274 therebetween. When the insulator 274 has a barrier property, diffusion of impurities from the insulator 280 into the oxide 230 can be prevented.

Of the conductor 240 (the conductor 240a and the conductor 240b), one functions as a source electrode and the other functions as a drain electrode.

A metal such as aluminum, titanium, chromium, nickel, copper, yttrium, zirconium, molybdenum, silver, tantalum, or tungsten or an alloy including any of the metals as its main component can be used for the conductor 240a and the conductor 240b. In particular, a metal nitride film of tantalum nitride or the like is preferable because it has a barrier property against hydrogen or oxygen and its oxidation resistance is high.

Although a single layer structure is shown in the drawing, a stacked-layer structure of two or more layers may be employed. For example, a tantalum nitride film and a tungsten film may be stacked. Alternatively, a titanium film and an aluminum film may be stacked. Other examples include a two-layer structure where an aluminum film is stacked over a tungsten film, a two-layer structure where a copper film is stacked over a copper-magnesium-aluminum alloy film, a two-layer structure where a copper film is stacked over a titanium film, and a two-layer structure where a copper film is stacked over a tungsten film.

Other examples include a three-layer structure where a titanium film or a titanium nitride film is formed, an aluminum film or a copper film is stacked over the titanium film or the titanium nitride film, and a titanium film or a titanium nitride film is stacked thereover, and a three-layer structure where a molybdenum film or a molybdenum nitride film is formed, an aluminum film or a copper film is stacked over the molybdenum film or the molybdenum nitride film, and a molybdenum film or a molybdenum nitride film is stacked thereover. Note that a transparent conductive material including indium oxide, tin oxide, or zinc oxide may be used.

A barrier layer may be provided so as to cover the conductor 240. The barrier layer is preferably formed using a substance having a barrier property against oxygen or hydrogen. With this structure, the conductor 240a and the conductor 240b can be inhibited from being oxidized when the insulator 274 is deposited.

A metal oxide can be used for the barrier layer, for example. In particular, an insulating film having a barrier property against oxygen or hydrogen, such as aluminum oxide, hafnium oxide, or gallium oxide, is preferably used. Alternatively, silicon nitride formed by a CVD method may be used.

With the barrier layer, the range of choices for the materials of the conductor 240 can be expanded. For example, a material having a low oxidation resistance and high conductivity, such as tungsten or aluminum, can be used for the conductor 240. Moreover, for example, a conductor that can be easily deposited and processed can be used.

The insulator 250 functions as a first gate insulator. The insulator 250 is preferably provided in the opening in the insulator 280 with the oxide 230c and the insulator 274 therebetween.

The insulator 250 may be formed using an insulator from which oxygen is released by heating. An example is an oxide film in which the amount of released oxygen converted into oxygen molecules is greater than or equal to 1.0×10¹⁸ molecules/cm³, preferably greater than or equal to 1.0×10¹⁹ molecules/cm³, further preferably greater than or equal to 2.0×10¹⁹ molecules/cm³ or greater than or equal to 3.0×10²⁰ molecules/cm³ in thermal desorption spectroscopy analysis (TDS analysis). Note that the temperature of the film surface in the TDS analysis is preferably higher than or equal to 100° C. and lower than or equal to 700° C.

Specifically, it is possible to use any of silicon oxide including excess oxygen, silicon oxynitride, silicon nitride oxide, silicon nitride, silicon oxide to which fluorine is added, silicon oxide to which carbon is added, silicon oxide to which carbon and nitrogen are added, and porous silicon oxide. In particular, silicon oxide and silicon oxynitride, which have thermal stability, are preferable.

When an insulator that releases oxygen by heating is provided for the insulator 250 in contact with the oxide 230c, oxygen can be efficiently supplied to the channel formation region of the oxide 230 from the insulator 250, so that oxygen vacancies included in the oxide 230 can be filled. As in the insulator 224, the concentration of impurities such as water or hydrogen included in the insulator 250 is preferably lowered.

That is, when an insulator having an excess oxygen region is provided in contact with the oxide 230 using the oxide semiconductor including cerium, even a small number of oxygen vacancies formed in the oxide 230 can be filled. Thus, a semiconductor device including a transistor having a high on-state current can be provided. Alternatively, a semiconductor device that has small variation in electrical characteristics, stable electrical characteristics, and high reliability can be provided.

Alternatively, for example, the insulator 250 may have a stacked-layer structure of a film from which oxygen is released by heating and a film having a barrier property. The film having a barrier property provided between the film from which oxygen is released by heating and the conductor 260 can prevent absorption of oxygen released by heating into the conductor 260. The film having a barrier property is preferably formed using a metal oxide including aluminum, hafnium, or the like. Since the metal oxide has a high dielectric constant, an equivalent oxide thickness (EOT) of the gate insulator can be reduced while the physical thickness is kept.

The conductor 260 functioning as the first gate electrode includes the conductor 260a and the conductor 260b over the conductor 260a. For the conductor 260a, like the conductor 205a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of oxygen atoms, oxygen molecules, and the like).

When the conductor 260a has a function of preventing diffusion of oxygen, diffusion of excess oxygen from the oxide 230 and the insulator 250 to the conductor 260b is suppressed. Thus, oxidation of the conductor 260b due to the excess oxygen included in the insulator 250 is suppressed, so that a decrease in conductivity can be prevented. Furthermore, a reduction in the amount of excess oxygen supplied to the oxide 230 can be inhibited.

As a conductive material having a function of inhibiting diffusion of oxygen, for example, tantalum, tantalum nitride, ruthenium, or ruthenium oxide is preferably used. The conductor 260a can be formed using an oxide semiconductor that can be used for the oxide 230. In that case, when the conductor 260b is deposited by a sputtering method, the conductor 260a can have a reduced electric resistance to be a conductor. This can be referred to as an OC (Oxide Conductor) electrode.

The conductor 260b is preferably formed using a conductive material including tungsten, copper, or aluminum as its main component. The conductor 260 functions as a wiring and thus is preferably formed using a conductor having high conductivity. For example, a conductive material including tungsten, copper, or aluminum as its main component can be used. The conductor 260b may have a stacked-layer structure, for example, a stacked layer of any of the above conductive materials and titanium or titanium nitride.

The insulator 274 is positioned between the insulator 280 and the transistor 200. For the insulator 274, an insulating material having a function of inhibiting the diffusion of oxygen and impurities such as water and hydrogen is preferably used. For example, aluminum oxide or hafnium oxide is preferably used. Other than that, a metal oxide such as magnesium oxide, gallium oxide, germanium oxide, yttrium oxide, zirconium oxide, lanthanum oxide, neodymium oxide, or tantalum oxide, silicon nitride oxide, silicon nitride, or the like can be used, for example.

The insulator 274 can prevent impurities such as water and hydrogen included in the insulator 280 from diffusing into the oxide 230b through the oxide 230c and the insulator 250. The insulator 274 can also prevent oxidation of the conductor 260 due to excess oxygen included in the insulator 280.

The insulator 280, the insulator 282, and the insulator 284 function as interlayer films.

As well as the insulator 214 and the insulator 274, the insulator 282 preferably functions as a barrier insulating film that inhibits impurities such as water or hydrogen from entering the transistor 200 from the outside.

Like the insulator 216, the insulator 280 and the insulator 284 preferably have lower dielectric constants than the insulator 214 and the insulator 282. When a material with a low dielectric constant is used for an interlayer film, parasitic capacitance generated between wirings can be reduced.

In addition, the transistor 200 may be electrically connected to another component through the plug or the wiring such as the conductor 246 embedded in the insulator 280, the insulator 282, and the insulator 284.

As a material for the conductor 246, like the conductor 205, a single layer or a stacked layer of a conductive material such as a metal material, an alloy material, a metal nitride material, or a metal oxide material can be used. For example, it is preferable to use a high-melting-point material that has both heat resistance and conductivity, such as tungsten or molybdenum. Alternatively, a low-resistance conductive material such as aluminum or copper is preferably used. The use of a low-resistance conductive material can reduce wiring resistance.

For example, when the conductor 246 has a stacked-layer structure of tungsten having high conductivity and tantalum nitride or the like that is a conductor having a barrier property against hydrogen and oxygen, diffusion of impurities from the outside can be inhibited while the conductivity of a wiring is ensured.

With the above structure, a semiconductor device that includes a transistor including an oxide semiconductor and having a high on-state current can be provided. Alternatively, a semiconductor device that includes a transistor including an oxide semiconductor and having a low off-state current can be provided. Alternatively, a semiconductor device that has small variation in electrical characteristics, stable electrical characteristics, and high reliability can be provided.

### <Structure 2 of Semiconductor Device>

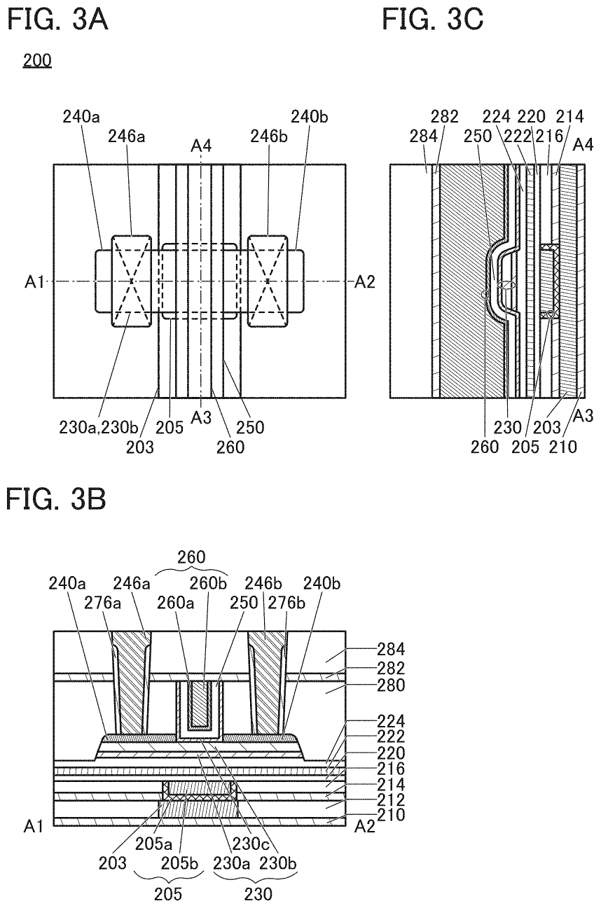

FIG. 3 illustrates an example of a semiconductor device including the transistor 200. FIG. 3(A) illustrates a top surface of the semiconductor device. For simplification of the drawing, some films are omitted in FIG. 3(A). FIG. 3(B) is a cross-sectional view corresponding to dashed-dotted line A1-A2 in FIG. 3(A), and FIG. 3(C) is a cross-sectional view corresponding to dashed-dotted line A3-A4 in FIG. 3(A).

Note that in the semiconductor device illustrated in FIG. 3, components having the same functions as the components included in the semiconductor device illustrated in FIG. 2 are denoted by the same reference numerals.

The insulator 274 is not necessarily provided in the semiconductor device illustrated in FIG. 3. For example, in the case where impurities such as hydrogen and water are sufficiently reduced in the insulator 280, the insulator 274 is unnecessary.

The insulator 280 may include an excess oxygen region. The excess oxygen included in the insulator 280 is diffused into the oxide 230b through the oxide 230c and the insulator 250, whereby oxygen vacancies in the oxide 230b can be filled.

When the insulator 280 includes an excess oxygen region, the insulator 276 (the insulator 276a and the insulator 276b) having a barrier property is preferably provided between the conductor 246 and the insulator 280. Providing the insulator 276 can prevent excess oxygen included in the insulator 280 from reacting with the conductor 246 to oxidize the conductor 246.

Furthermore, with the insulator 276 having a barrier property, the range of choices for the materials of the conductor used for a plug or a wiring can be expanded. For example, the use of a metal material having an oxygen absorbing property and high conductivity for the conductor 246 can provide a semiconductor device with low power consumption. As specific examples, a material having a low oxidation resistance and high conductivity, such as tungsten or aluminum, can be used. Moreover, for example, a conductor that can be easily deposited and processed can be used.

The oxide 235 is not necessarily provided in the semiconductor device illustrated in FIG. 3. For example, the conductor 240 is formed using a hardly oxidizable material. In the case where the contact resistance with the oxide 230 is sufficiently low, the oxide 235 is unnecessary.

### <Structure 3 of Semiconductor Device>

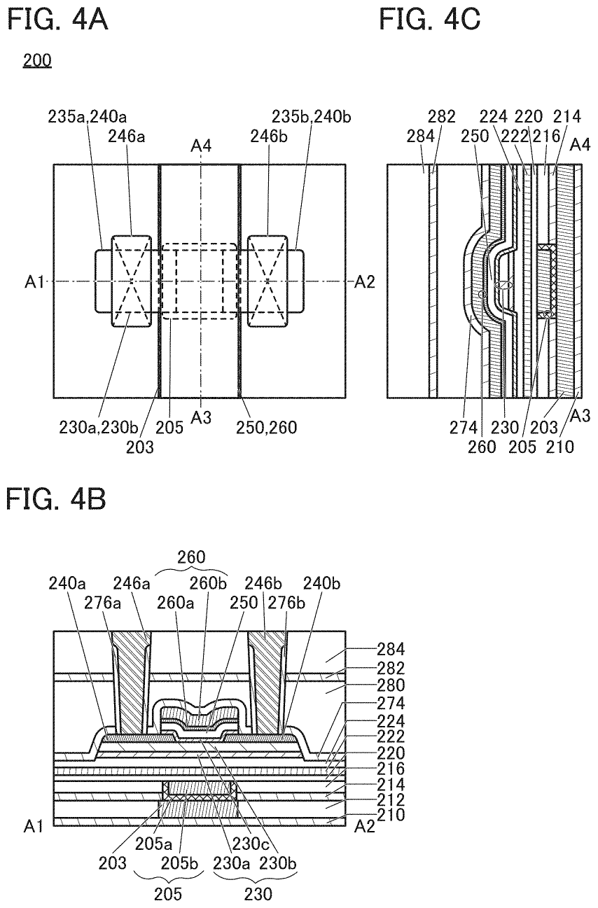

FIG. 4 illustrates an example of a semiconductor device including the transistor 200. FIG. 4(A) illustrates a top surface of the semiconductor device. For simplification of the drawing, some films are omitted in FIG. 4(A). FIG. 4(B) is a cross-sectional view corresponding to dashed-dotted line A1-A2 in FIG. 4(A), and FIG. 4(C) is a cross-sectional view corresponding to dashed-dotted line A3-A4.

Note that in the semiconductor device illustrated in FIG. 4, structures having the same functions as the structures included in the semiconductor device illustrated in FIG. 2 and FIG. 3 are denoted by the same reference numerals.

In the semiconductor device illustrated in FIG. 4, the conductor 240 and the oxide 230c, the insulator 250, and the conductor 260 overlap with each other. With the structure, a transistor with a high on-state current can be provided. Alternatively, a transistor having high controllability can be provided.

The insulator 274 is preferably provided to cover the top surface and side surfaces of the conductor 260, the side surfaces of the insulator 250, and the side surfaces of the oxide 230c. The provision of the insulator 274 can inhibit oxidation of the conductor 260. In addition, diffusion of impurities included in the insulator 280 into the oxide 230b through the oxide 230c and the insulator 250 can be suppressed.

Note that an excess oxygen region may be provided in the insulator 280. In the case where the insulator 280 includes an excess oxygen region, an opening (not illustrated) exposing the insulator 224 may be provided in the insulator 274. Furthermore, an insulator through which oxygen is diffused may be used as the insulator 224 in contact with the oxide 230.

With the above structure, the insulator 274 that inhibits diffusion of oxygen is provided between the insulator 224 and the insulator 280 including an excess oxygen region. On the other hand, the insulator 274 includes an opening; thus, the insulator 280 is in contact with the insulator 224 through the opening. The opening included in the insulator 274 may be designed as appropriate depending on the shape, size, integration degree, or layout of the transistor 200. For example, the shape of the opening may be a circular or polygonal hole, groove, slit, or the like. That is, the excess oxygen included in the insulator 280 can reduce oxygen vacancies in the oxide 230 through the insulator 224. Note that the impurities included in the insulator 280 can be prevented from being diffused into the oxide 230b by adjusting the thickness of the oxide 230a.

### <Structure 4 of Semiconductor Device>

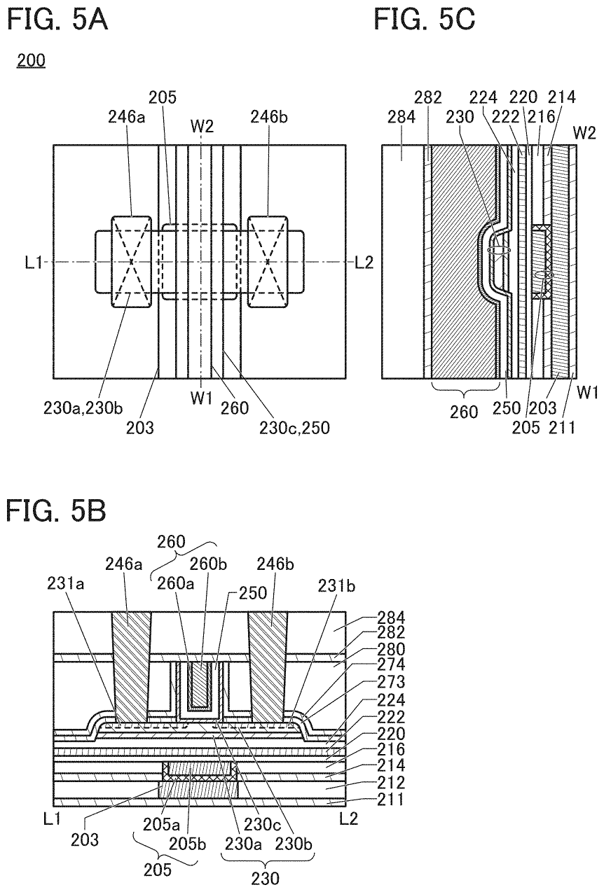

FIG. 5 illustrates an example of a semiconductor device including the transistor 200. FIG. 5(A) illustrates a top surface of the semiconductor device. For simplification of the drawing, some films are omitted in FIG. 5(A). FIG. 5(B) is a cross-sectional view corresponding to dashed-dotted line L1-L2 in FIG. 5(A), and FIG. 5(C) is a cross-sectional view corresponding to dashed-dotted line W1-W2.

Note that in the semiconductor device illustrated in FIG. 5, structures having the same functions as the structures included in the semiconductor device illustrated in FIG. 2, FIG. 3, and FIG. 4 are denoted by the same reference numerals.

In FIGS. 5(A) to 5(C), the conductor 240 is not provided, and a region 231a and a region 231b are included in part of the exposed top surface of the oxide 230b. One of the region 231a and the region 231b functions as a source region and the other functions as a drain region. Moreover, an insulator 273 is provided between the oxide 230b and the insulator 274.

The region 231 (the region 231a and the region 231b) illustrated in FIG. 5 is a region whose resistance is reduced by addition of an element described later to the oxide 230b. The region 231 can be formed using a dummy gate, for example.

Specifically, the dummy gate is provided over the oxide 230b, and an element that reduces the resistance of the oxide 230b is preferably added using the dummy gate as a mask. That is, the element is added to a region of the oxide 230 that does not overlap with the dummy gate, so that the region 231 is formed. Note that for the addition method of the element, an ion implantation method by which an ionized source gas is subjected to mass separation and then added, an ion doping method by which an ionized source gas is added without mass separation, a plasma immersion ion implantation method, or the like can be used.

As the element that reduces the resistance of the oxide 230, boron or phosphorus is typically used. Hydrogen, carbon, nitrogen, fluorine, sulfur, chlorine, titanium, a rare gas, or the like can also be used. Typical examples of the rare gas include helium, neon, argon, krypton, and xenon. The concentration of the above element may be measured by secondary ion mass spectrometry (SIMS) or the like.

In particular, boron and phosphorus are preferably used because an apparatus used in a manufacturing line for amorphous silicon or low-temperature polysilicon can be used. Since the existing facility can be used, capital investment can be reduced.

Next, an insulating film to be the insulator 273 and an insulating film to be the insulator 274 may be formed over the oxide 230b and the dummy gate. The insulating film to be the insulator 273 and the insulator 274 are stacked and provided, whereby a region where the region 231 and the oxide 230c and the insulator 250 overlap with each other can be provided.

Specifically, after an insulating film to be the insulator 280 is provided over the insulating film to be the insulator 274, the insulating film to be the insulator 280 is subjected to CMP (Chemical Mechanical Polishing) treatment, whereby part of the insulating film to be the insulator 280 is removed and the dummy gate is exposed. Then, when the dummy gate is removed, part of the insulator 273 in contact with the dummy gate is preferably also removed. Thus, the insulator 274 and the insulator 273 are exposed at the side surface of the opening provided in the insulator 280, and the region 231 provided in the oxide 230b is partly exposed at the bottom surface of the opening. Next, an oxide film to be the oxide 230c, an insulating film to be the insulator 250, and a conductive film to be the conductor 260 are formed in this order in the opening, and then the oxide film to be the oxide 230c, the insulating film to be the insulator 250, and the conductive film to be the conductor 260 are partly removed by CMP treatment or the like until the insulator 280 is exposed, whereby the transistor illustrated in FIG. 5 can be formed.

Note that the insulator 273 and the insulator 274 are not necessarily provided. Design is appropriately set in consideration of required transistor characteristics.

For the transistor illustrated in FIG. 5, existing apparatuses can be used, and the conductor 240 is not provided; thus, the cost can be reduced.

With the above structure, a semiconductor device that includes a transistor including an oxide semiconductor and having a high on-state current can be provided. Alternatively, a semiconductor device that includes a transistor including an oxide semiconductor and having a low off-state current can be provided. Alternatively, a semiconductor device that has small variation in electrical characteristics, stable electrical characteristics, and improved reliability can be provided.

The structure, method, and the like described above in this embodiment can be used in combination as appropriate with the structures, methods, and the like described in the other embodiments.

### Embodiment 3

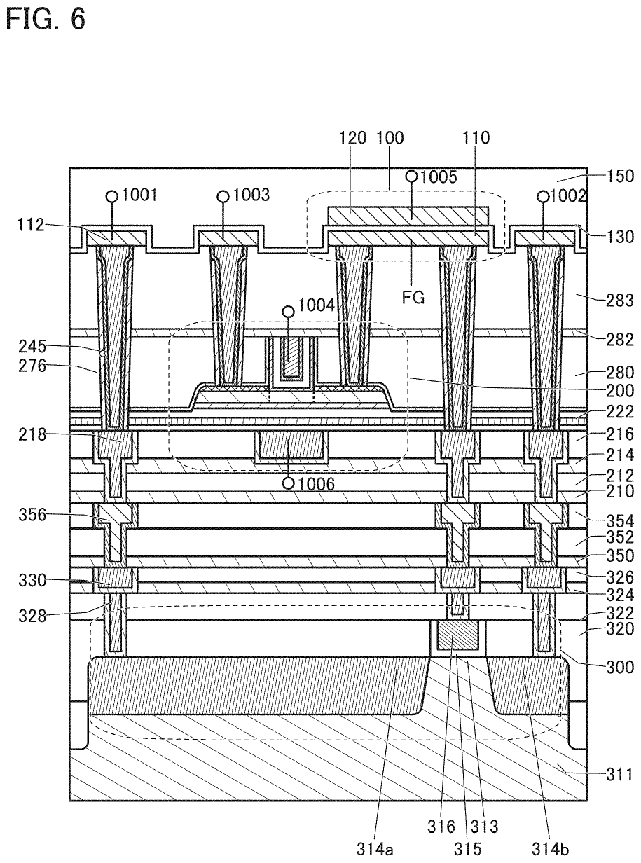

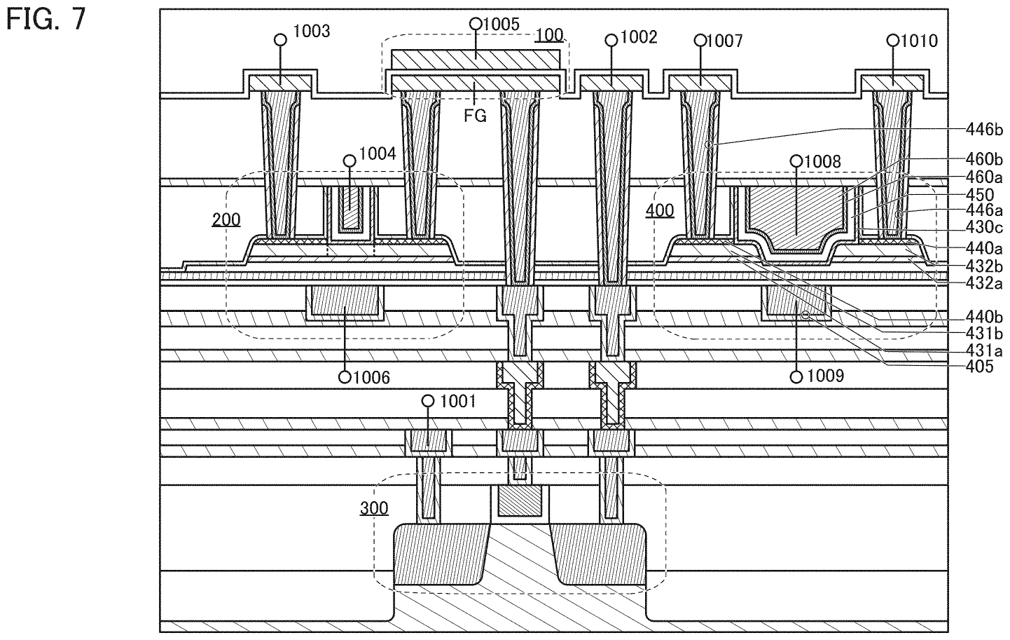

In this embodiment, one embodiment of a semiconductor device is described with reference to FIG. 6 and FIG. 7.

### [Memory Device 1]

FIG. 6 illustrates an example of a semiconductor device (memory device) in which the capacitor of one embodiment of the present invention is used. In the semiconductor device of one embodiment of the present invention, the transistor 200 is provided above a transistor 300, and a capacitor 100 is provided above the transistor 300 and the transistor 200. The transistor 200 described in the above embodiment can be used as the transistor 200.

The transistor 200 is a transistor whose channel is formed in a semiconductor layer including an oxide semiconductor. Since the transistor 200 has a low off-state current, a memory device including the transistor 200 can retain stored data for a long time. In other words, such a memory device does not require refresh operation or has an extremely low frequency of the refresh operation, which leads to a sufficient reduction in power consumption of the memory device.

In the semiconductor device illustrated in FIG. 6, a wiring 1001 is electrically connected to a source of the transistor 300, and a wiring 1002 is electrically connected to a drain of the transistor 300. A wiring 1003 is electrically connected to one of the source and the drain of the transistor 200. A wiring 1004 is electrically connected to a first gate of the transistor 200. A wiring 1006 is electrically connected to a second gate of the transistor 200. A gate of the transistor 300 and the other of the source and the drain of the transistor 200 are electrically connected to one electrode of the capacitor 100. A wiring 1005 is electrically connected to the other electrode of the capacitor 100.

By arranging the memory devices illustrated in FIG. 6 in a matrix, a memory cell array can be formed.

### <Transistor 300>

The transistor 300 is provided over a substrate 311 and includes a conductor 316 functioning as a gate electrode, an insulator 315 functioning as a gate insulator, a semiconductor region 313 that is a part of the substrate 311, and a low-resistance region 314a and a low-resistance region 314b functioning as the source region and the drain region. The transistor 300 may be a p-channel transistor or an n-channel transistor.

In the transistor 300 illustrated in FIG. 6, the semiconductor region 313 (part of the substrate 311) where the channel is formed has a projecting portion. Furthermore, the conductor 316 is provided to cover the top and side surfaces of the semiconductor region 313 with the insulator 315 therebetween. Note that the conductor 316 may be formed using a material for adjusting the work function. The transistor 300 having such a structure is also referred to as a FIN transistor because the projecting portion of the semiconductor substrate is utilized. An insulator functioning as a mask for forming the projecting portion may be provided in contact with the top surface of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 6 is just an example and the structure of the transistor 300 is not limited to that illustrated therein; an appropriate transistor may be used in accordance with a circuit configuration or a driving method.

### <Capacitor 100>

The capacitor 100 is provided above the transistor 200. The capacitor 100 includes a conductor 110 functioning as a first electrode, a conductor 120 functioning as a second electrode, and an insulator 130 functioning as a dielectric.

For example, a conductor 112 and the conductor 110 over the conductor 246 can be formed at the same time. Note that the conductor 112 functions as a plug or a wiring that is electrically connected to the capacitor 100, the transistor 200, or the transistor 300.

The conductor 112 and the conductor 110 each have a single-layer structure in FIG. 6; however, one embodiment of the present invention is not limited thereto, and a stacked-layer structure of two or more layers may be used. For example, between a conductor having a barrier property and a conductor having high conductivity, a conductor which is highly adhesive to the conductor having a barrier property and the conductor having high conductivity may be formed.

The insulator 130 can be formed to have a single-layer structure or a stacked-layer structure using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or the like.

For example, the insulator 130 preferably has a stacked-layer structure using a material with high dielectric strength such as silicon oxynitride and a high dielectric constant (high-k) material. In the capacitor 100 having such a structure, a sufficient capacitance can be provided owing to the high dielectric constant (high-k) insulator, and the dielectric strength can be increased owing to the insulator with high dielectric strength, so that the electrostatic breakdown of the capacitor 100 can be prevented.

As the insulator using a high dielectric constant (high-k) material (a material having a high dielectric constant), gallium oxide, hafnium oxide, zirconium oxide, an oxide including aluminum and hafnium, an oxynitride including aluminum and hafnium, an oxide including silicon and hafnium, an oxynitride including silicon and hafnium, a nitride including silicon and hafnium, or the like can be given.

As the material having a high dielectric strength (a material having a low dielectric constant), silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like can be given.

### <Wiring Layers>

Wiring layers provided with an interlayer film, a wiring, a plug, and the like may be provided between the structure bodies. A plurality of wiring layers can be provided in accordance with the design. Note that a plurality of conductors functioning as plugs or wirings are collectively denoted by the same reference numeral in some cases. Furthermore, in this specification and the like, a wiring and a plug electrically connected to the wiring may be a single component. That is, part of a conductor functions as a wiring in some cases and part of a conductor functions as a plug in other cases.

For example, an insulator 320, an insulator 322, an insulator 324, and an insulator 326 are stacked over the transistor 300 in this order as interlayer films. A conductor 328, a conductor 330, and the like that are electrically connected to the capacitor 100 or the transistor 200 are provided in the insulator 320, the insulator 322, the insulator 324, and the insulator 326. Note that the conductor 328 and the conductor 330 each function as a plug or a wiring.

The insulator functioning as an interlayer film may function as a planarization film that covers a roughness thereunder. For example, the top surface of the insulator 322 may be planarized by planarization treatment using a chemical mechanical polishing (CMP) method or the like to improve planarity.

A wiring layer may be provided over the insulator 326 and the conductor 330. For example, in FIG. 6, an insulator 350, an insulator 352, and an insulator 354 are stacked in this order. Furthermore, a conductor 356 is formed in the insulator 350, the insulator 352, and the insulator 354. The conductor 356 functions as a plug or a wiring.

Similarly, a conductor 218, a conductor (the conductor 205) included in the transistor 200, and the like are provided in the insulator 210, the insulator 212, the insulator 214, and the insulator 216. Note that the conductor 218 functions as a plug or a wiring that is electrically connected to the capacitor 100 or the transistor 300. In addition, an insulator 150 is provided over the conductor 120 and the insulator 130.

Examples of an insulator that can be used as an interlayer film include an insulating oxide, an insulating nitride, an insulating oxynitride, an insulating nitride oxide, an insulating metal oxide, an insulating metal oxynitride, and an insulating metal nitride oxide.

For example, when a material having a low dielectric constant is used for the insulator functioning as an interlayer film, the parasitic capacitance between wirings can be reduced. Accordingly, a material is preferably selected in accordance with the function of an insulator.

For example, the insulator 150, the insulator 212, the insulator 352, the insulator 354, and the like preferably include an insulator having a low dielectric constant. For example, the insulator preferably includes silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. Alternatively, the insulator preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. Because silicon oxide and silicon oxynitride have thermal stability, a combination of silicon oxide or silicon oxynitride with a resin allows the stacked-layer structure to be thermally stable and have a low dielectric constant. Examples of the resin include polyester, polyolefin, polyamide (e.g., nylon and aramid), polyimide, polycarbonate, and acrylic.

Note that when the transistor including an oxide semiconductor is surrounded by an insulator having a function of inhibiting the passage of oxygen and impurities such as hydrogen, the electrical characteristics of the transistor can be stabilized. Thus, the insulator having a function of inhibiting the passage of oxygen and impurities such as hydrogen is preferably used for the insulator 210, the insulator 350, and the like.

The insulator having a function of inhibiting the passage of oxygen and impurities such as hydrogen can have, for example, a single-layer structure or a stacked-layer structure of an insulator including boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulator having a function of inhibiting the passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

The conductors that can be used for wirings or plugs can be formed using a material including one or more metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like. Alternatively, a semiconductor having a high electric conductivity typified by polycrystalline silicon including an impurity element such as phosphorus, or silicide such as nickel silicide may be used.

For example, the conductor 328, the conductor 330, the conductor 356, the conductor 218, the conductor 112, and the like may have a single-layer structure or a stacked-layer structure using a conductive material such as a metal material, an alloy material, a metal nitride material, or a metal oxide material that is formed using the above materials. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

<<Wirings or Plugs in a Layer Provided with an Oxide Semiconductor>>

In the case where an oxide semiconductor is used in the transistor 200, an insulator including an excess oxygen region is provided in the vicinity of the oxide semiconductor in some cases. In that case, an insulator having a barrier property is preferably provided between the insulator including the excess oxygen region and the conductor provided in the insulator including the excess oxygen region.

For example, the insulator 276 is preferably provided between the insulator 224 and the conductor 246 in FIG. 6. In particular, the insulator 276 is preferably provided in contact with the insulator 274 and the insulator 222 that sandwich the insulator 224 including an excess oxygen region therebetween. Since the insulator 276 is provided in contact with the insulator 222 and the insulator 274, the insulator 224 and the transistor 200 can be sealed by the insulators having a barrier property. It is also preferable that the insulator 276 be in contact with part of the insulator 280. When the insulator 276 extends to the insulator 280, diffusion of oxygen and impurities can be further inhibited.

That is, the insulator 276 can inhibit excess oxygen included in the insulator 224 from being absorbed by the conductor 246. In addition, the insulator 276 can inhibit diffusion of hydrogen, which is an impurity, into the transistor 200 through the conductor 246.

The insulator 276 is preferably formed using an insulating material having a function of inhibiting diffusion of oxygen and impurities such as water or hydrogen. For example, aluminum oxide or hafnium oxide is preferably used. Alternatively, for example, a metal oxide such as magnesium oxide, gallium oxide, germanium oxide, yttrium oxide, zirconium oxide, lanthanum oxide, neodymium oxide, or tantalum oxide; silicon nitride oxide; or silicon nitride can be used.

The above is the description of the structure example. With the use of the structure, a semiconductor device using a transistor including an oxide semiconductor can have a small variation in electrical characteristics and higher reliability. Alternatively, a transistor including an oxide semiconductor with a high on-state current can be provided. Alternatively, a transistor including an oxide semiconductor with low off-state current can be provided. Alternatively, a semiconductor device with low power consumption can be provided.

### [Memory Device 2]

FIG. 7 illustrates an example of a memory device using the semiconductor device of one embodiment of the present invention. The memory device illustrated in FIG. 7 includes a transistor 400 in addition to the semiconductor device that includes the transistor 200, the transistor 300, and the capacitor 100 illustrated in FIG. 6.

The transistor 400 can control a second gate voltage of the transistor 200. For example, a first gate and a second gate of the transistor 400 are diode-connected to a source, and the source of the transistor 400 is connected to the second gate of the transistor 200. When a negative potential of the second gate of the transistor 200 is held in this structure, a first gate-source voltage and a second gate-source voltage of the transistor 400 are 0 V. In the transistor 400, a drain current when the second gate voltage and the first gate voltage are 0 V is extremely low; thus, the negative potential of the second gate of the transistor 200 can be held for a long time even without power supply to the transistor 200 and the transistor 400. Accordingly, the memory device including the transistor 200 and the transistor 400 can retain stored data for a long time.

In FIG. 7, the wiring 1001 is electrically connected to the source of the transistor 300, and the wiring 1002 is electrically connected to the drain of the transistor 300. The wiring 1003 is electrically connected to one of the source and the drain of the transistor 200, the wiring 1004 is electrically connected to the gate of the transistor 200, and the wiring 1006 is electrically connected to a back gate of the transistor 200. The gate of the transistor 300 and the other of the source and the drain of the transistor 200 are electrically connected to one electrode of the capacitor 100. The wiring 1005 is electrically connected to the other electrode of the capacitor 100. A wiring 1007 is electrically connected to the source of the transistor 400. A wiring 1008 is electrically connected to a gate of the transistor 400. A wiring 1009 is electrically connected to a back gate of the transistor 400. A wiring 1010 is electrically connected to the drain of the transistor 400. The wiring 1006, the wiring 1007, the wiring 1008, and the wiring 1009 are electrically connected to each other.

When the memory devices in FIG. 7 are arranged in a matrix like the memory devices illustrated in FIG. 6, a memory cell array can be formed. Note that one transistor 400 can control second gate voltages of a plurality of transistors 200. For this reason, the number of transistors 400 is preferably smaller than the number of transistors 200.

### <Transistor 400>

The transistor 400 and the transistors 200 are formed in the same layer and thus can be fabricated in parallel. The transistor 400 includes a conductor 460 (a conductor 460a and a conductor 460b) functioning as a first gate electrode; a conductor 405 (a conductor 405a and a conductor 405b) functioning as a second gate electrode; the insulator 220, the insulator 222, the insulator 224, and an insulator 450 functioning as a gate insulating layer; an oxide 430c including a channel formation region; a conductor 440a, an oxide 431a, and an oxide 431b functioning as one of a source and a drain; a conductor 440b, an oxide 432a, and an oxide 432b functioning as the other of the source and the drain; and a conductor 446 (a conductor 446a and a conductor 446b).

In the transistor 400, the conductor 405 is in the same layer as the conductor 205. The oxide 431a and the oxide 432a are in the same layer as the oxide 230a, and the oxide 431b and the oxide 432b are in the same layer as the oxide 230b. The conductor 440 is in the same layer as the conductor 240. The oxide 430c is in the same layer as the oxide 230c. The insulator 450 is in the same layer as the insulator 250. The conductor 460 is in the same layer as the conductor 260.

Note that the structure body in the same layer can be formed at the same time. For example, the oxide 430c can be formed by processing an oxide film to be the oxide 230c.

In the oxide 430c functioning as an active layer of the transistor 400, oxygen vacancies and impurities such as hydrogen or water are reduced, as in the oxide 230 or the like. Accordingly, the threshold voltage of the transistor 400 can be higher than 0 V, an off-state current can be reduced, and the drain current when the second gate voltage and the first gate voltage are 0 V can be extremely low.

### <<Dicing Line>>

Here, a dicing line (also referred to as a scribe line, a dividing line, or a cutting line) that is provided when a large-sized substrate is divided into semiconductor elements so that a plurality of semiconductor devices are each formed in a chip form is described below. In an example of a dividing method, for example, a groove (a dicing line) for separating the semiconductor elements is formed on the substrate, and then the substrate is cut along the dicing line so that a plurality of semiconductor devices that are separated are obtained.

Here, for example, as illustrated in FIG. 7, it is preferable that a region in which the insulator 274 and the insulator 222 are in contact with each other be the dicing line. That is, an opening is provided in the insulator 224 in the vicinity of the region to be the dicing line that is provided in an outer edge of the transistor 400 and the memory cell including a plurality of transistors 200. The insulator 274 is provided to cover the side surface of the insulator 224.

That is, in the opening provided in the insulator 224, the insulator 222 is in contact with the insulator 274. For example, the insulator 222 and the insulator 274 may be formed using the same material and the same method. When the insulator 222 and the insulator 274 are formed using the same material and the same method, the adhesion therebetween can be increased. For example, aluminum oxide is preferably used.

With such a structure, the insulator 224, the transistor 200 and the transistor 400 can be enclosed with the insulator 222 and the insulator 274. Since the insulator 222 and the insulator 274 have a function of inhibiting diffusion of oxygen, hydrogen, and water even when the substrate is divided into circuit regions each of which is provided with the semiconductor elements in this embodiment to form a plurality of chips, the entry and diffusion of impurities such as hydrogen or water from the direction of a side surface of the divided substrate to the transistor 200 or the transistor 400 can be inhibited.

Furthermore, in the structure, excess oxygen in the insulator 224 can be inhibited from being diffused into the outside of the insulator 274 and the insulator 222. Accordingly, excess oxygen in the insulator 224 is efficiently supplied to the oxide where the channel is formed in the transistor 200 or the transistor 400. The oxygen can reduce oxygen vacancies in the oxide where the channel is formed in the transistor 200 or the transistor 400. Thus, the oxide where the channel is formed in the transistor 200 or the transistor 400 can be an oxide semiconductor with a low density of defect states and stable characteristics. That is, the transistor 200 or the transistor 400 can have a small variation in the electrical characteristics and higher reliability.

This embodiment can be implemented in an appropriate combination with any of the structures described in the other embodiments and the like.

### Embodiment 4

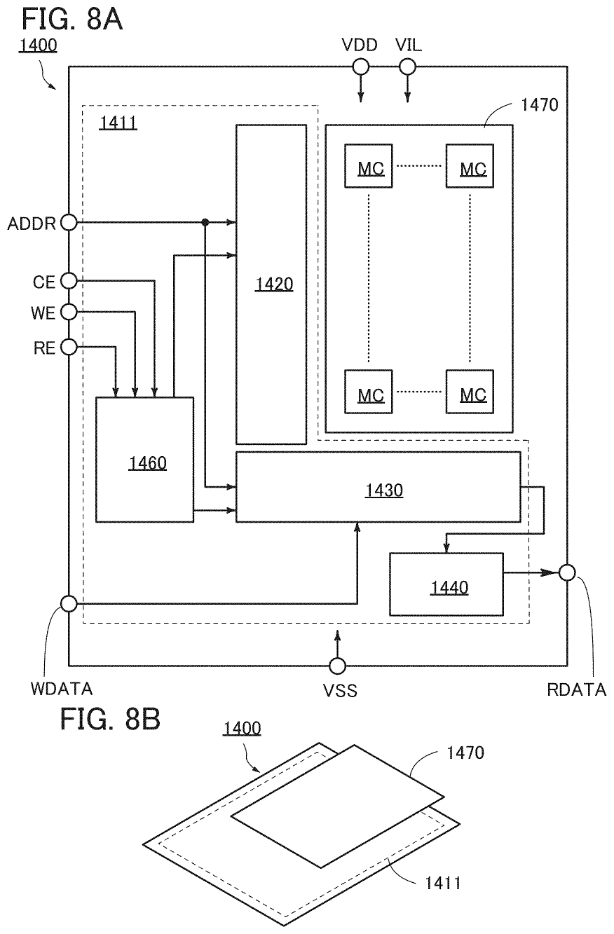

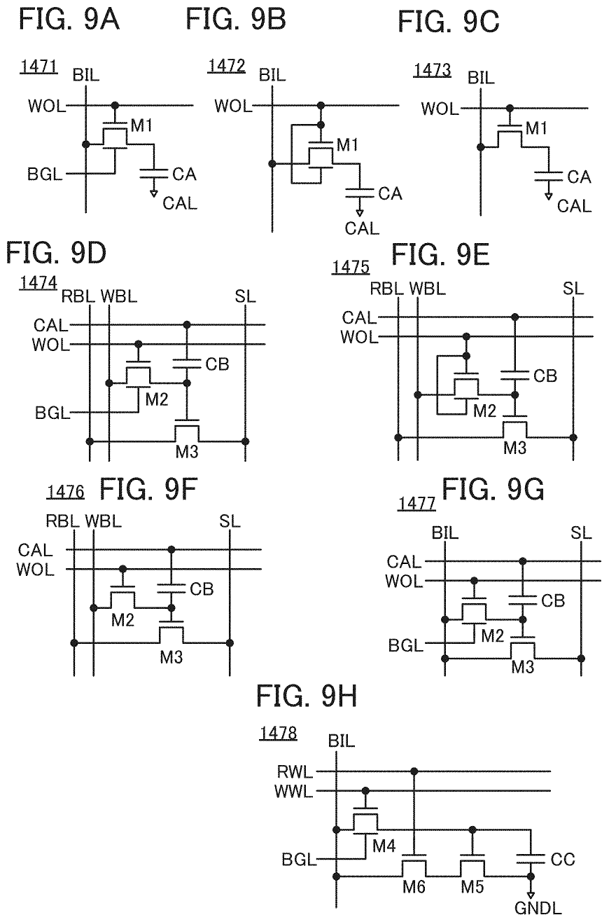

In this embodiment, a memory device of one embodiment of the present invention including a transistor in which an oxide is used for a semiconductor (hereinafter referred to as an OS transistor in some cases) and a capacitor (hereinafter, such a memory device is also referred to as an OS memory device in some cases), is described with reference to FIG. 8 and FIG. 9. The OS memory device includes at least a capacitor and an OS transistor that controls the charging and discharging of the capacitor. Since the OS transistor has an extremely low off-state current, the OS memory device has excellent retention characteristics and thus can function as a nonvolatile memory.

### <Structure Example of Memory Device>

FIG. 8(A) illustrates a structure example of the OS memory device. A memory device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to the memory cell included in the memory cell array 1470, and are described later. The amplified data signal is output as a data signal RDATA to the outside of the memory device 1400 through the output circuit 1440. The row circuit 1420 includes, for example, a row decoder and a word line driver circuit, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the memory device 1400. Control signals (CE, WE, and RE), an address signal ADDR, and a data signal WDATA are also input to the memory device 1400 from the outside. The address signal ADDR is input to the row decoder and the column decoder, and the data signal WDATA is input to the write circuit.

The control logic circuit 1460 processes the signals (CE, WE, and RE) input from the outside, and generates control signals for the row decoder and the column decoder. CE is a chip enable signal, WE is a write enable signal, and RE is a read enable signal. Signals processed by the control logic circuit 1460 are not limited thereto, and other control signals may be input as necessary.

The memory cell array 1470 includes a plurality of memory cells MC and a plurality of wirings arranged in a matrix. Note that the number of the wirings that connect the memory cell array 1470 to the row circuit 1420 depends on the configuration of the memory cell MC, the number of the memory cells MC in a column, and the like. The number of the wirings that connect the memory cell array 1470 to the column circuit 1430 depends on the configuration of the memory cell MC, the number of the memory cells MC in a row, and the like.

Note that FIG. 8(A) illustrates an example in which the peripheral circuit 1411 and the memory cell array 1470 are formed on the same plane; however, this embodiment is not limited thereto. For example, as illustrated in FIG. 8(B), the memory cell array 1470 may be provided over the peripheral circuit 1411 to partly overlap with the peripheral circuit 1411. For example, the sense amplifier may be provided below the memory cell array 1470 so that they overlap with each other.

FIG. 9 illustrates configuration examples of a memory cell applicable to the memory cell MC.

### [DOSRAM]

FIGS. 9(A) to 9(C) each illustrate a circuit configuration example of a memory cell of a DRAM. In this specification and the like, a DRAM using a memory cell including one OS transistor and one capacitor is referred to as a dynamic oxide semiconductor random access memory (DOSRAM) in some cases. A memory cell 1471 illustrated in FIG. 9(A) includes a transistor M1 and a capacitor CA. Note that the transistor M1 includes a gate (also referred to as a front gate in some cases) and a back gate.

A first terminal of the transistor M1 is connected to a first terminal of the capacitor CA, a second terminal of the transistor M1 is connected to a wiring BIL, the gate of the transistor M1 is connected to a wiring WOL, and the back gate of the transistor M1 is connected to a wiring BGL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. In the time of data writing and data reading, a low-level potential is preferably applied to the wiring CAL. The wiring BGL functions as a wiring for applying a potential to the back gate of the transistor M1. When a given potential is applied to the wiring BGL, the threshold voltage of the transistor M1 can be changed.

The circuit configuration of the memory cell MC is not limited to that of the memory cell 1471, and the circuit configuration can be changed. For example, as in a memory cell 1472 illustrated in FIG. 9(B), the back gate of the transistor M1 may be connected not to the wiring BGL but to the wiring WOL in the memory cell MC. As another example, the memory cell MC may be composed of a single-gate transistor, that is, the transistor M1 without a back gate, like a memory cell 1473 illustrated in FIG. 9(C).

In the case where the semiconductor device described in any of the above embodiments is used in the memory cell 1471 and the like, the transistor 200 can be used as the transistor M1, and the capacitor 100 can be used as the capacitor CA. When an OS transistor is used as the transistor M1, the leakage current of the transistor M1 can be extremely low. That is, with the use of the transistor M1, written data can be retained for a long time, and thus the frequency of the refresh operation for the memory cell can be decreased. In addition, refresh operation for the memory cell can be omitted. In addition, since the transistor M1 has an extremely low leakage current, multi-level data or analog data can be retained in the memory cell 1471, the memory cell 1472, and the memory cell 1473.

In the DOSRAM, when the sense amplifier is provided below the memory cell array 1470 so that they overlap with each other as described above, the bit line can be shortened. A shorter bit line results in smaller bit line capacitance, which allows the storage capacitance of the memory cell to be reduced.

### [NOSRAM]

FIGS. 9(D) to 9(G) each illustrate a circuit configuration example of a gain-cell memory cell including two transistors and one capacitor. A memory cell 1474 illustrated in FIG. 9(D) includes a transistor M2, a transistor M3, and a capacitor CB. Note that the transistor M2 includes a front gate (simply referred to as a gate in some cases) and a back gate. In this specification and the like, a memory device including a gain-cell memory cell using an OS transistor as the transistor M2 is referred to as a nonvolatile oxide semiconductor RAM (NOSRAM) in some cases.

A first terminal of the transistor M2 is connected to a first terminal of the capacitor CB. A second terminal of the transistor M2 is connected to a wiring WBL. A gate of the transistor M2 is connected to the wiring WOL. A back gate of the transistor M2 is connected to the wiring BGL. A second terminal of the capacitor CB is connected to the wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing, data retaining, and data reading, a low-level potential is preferably applied to the wiring CAL. The wiring BGL functions as a wiring for applying a potential to the back gate of the transistor M2. The threshold voltage of the transistor M2 can be increased or decreased by supplying a given potential to the wiring BGL.

The circuit configuration of the memory cell MC is not limited to that of the memory cell 1474, and the circuit configuration can be changed as appropriate. For example, as in a memory cell 1475 illustrated in FIG. 9(E), the back gate of the transistor M2 may be connected not to the wiring BGL but to the wiring WOL in the memory cell MC. Alternatively, for example, the memory cell MC may be a memory cell including as single-gate transistor, that is, the transistor M2 not including a back gate, as in a memory cell 1476 illustrated in FIG. 9(F). For example, the memory cell MC may have a structure where the wiring WBL and the wiring RBL are combined into one wiring BIL as in a memory cell 1477 illustrated in FIG. 9(G).

In the case where the semiconductor device described in any of the above embodiments is used in the memory cell 1474 and the like, the transistor 200 can be used as the transistor M2, the transistor 300 can be used as the transistor M3, and the capacitor 100 can be used as the capacitor CB. When an OS transistor is used as the transistor M2, the leakage current of the transistor M2 can be extremely low. That is, with the use of the transistor M2, written data can be retained for a long time, and thus the frequency of the refresh operation for the memory cell can be decreased. In addition, refresh operation for the memory cell can be omitted. In addition, since the transistor M2 has an extremely low leakage current, multi-level data and analog data can be retained in the memory cell 1474. The same applies to the memory cells 1475 to 1477.

Note that the transistor M3 may be a transistor including silicon in a channel formation region (hereinafter, also referred to as a Si transistor in some cases). The Si transistor may be either an n-channel transistor or a p-channel transistor. The Si transistor has higher field-effect mobility than the OS transistor in some cases. Therefore, a Si transistor may be used as the transistor M3 functioning as a reading transistor. Furthermore, the transistor M2 can be formed over the transistor M3 when a Si transistor is used as the transistor M3, in which case the area of the memory cell can be reduced, leading to high integration of the memory device.

Alternatively, the transistor M3 may be an OS transistor. When an OS transistor is used as each of the transistors M2 and M3, the memory cell array 1470 can be formed using single-polarity circuits.

FIG. 9(H) illustrates an example of a gain-cell memory cell including three transistors and one capacitor. A memory cell 1478 illustrated in FIG. 9(H) includes transistors M4 to M6 and a capacitor CC. The capacitor CC is provided as appropriate. The memory cell 1478 is electrically connected to the wirings BIL, RWL, WWL, BGL, and GNDL. The wiring GNDL is a wiring for supplying a low-level potential. Note that the memory cell 1478 may be electrically connected to the wirings RBL and WBL instead of the wiring BIL.

The transistor M4 is an OS transistor with a back gate that is electrically connected to the wiring BGL. Note that the back gate and the gate of the transistor M4 may be electrically connected to each other. Alternatively, the back gate is not necessarily provided in the transistor M4.

Note that each of the transistors M5 and M6 may be an n-channel Si transistor or a p-channel Si transistor. Alternatively, the transistors M4 to M6 may be OS transistors, in which case the memory cell array 1470 can be formed using single-polarity transistors.

In the case where the semiconductor device described in any of the above embodiments is used in the memory cell 1478, the transistor 200 can be used as the transistor M4, the transistor 300 can be used as the transistors M5 and M6, and the capacitor 100 can be used as the capacitor CC. When an OS transistor is used as the transistor M4, the leakage current of the transistor M4 can be extremely low.

Note that the configurations of the peripheral circuit 1411, the memory cell array 1470, and the like described in this embodiment are not limited to those described above. The positions or functions of these circuits, wirings connected to the circuits, circuit elements, and the like can be changed, deleted, or added as needed.

The structures described in this embodiment can be used in appropriate combination with any of the structures described in the other embodiments.

### Embodiment 5

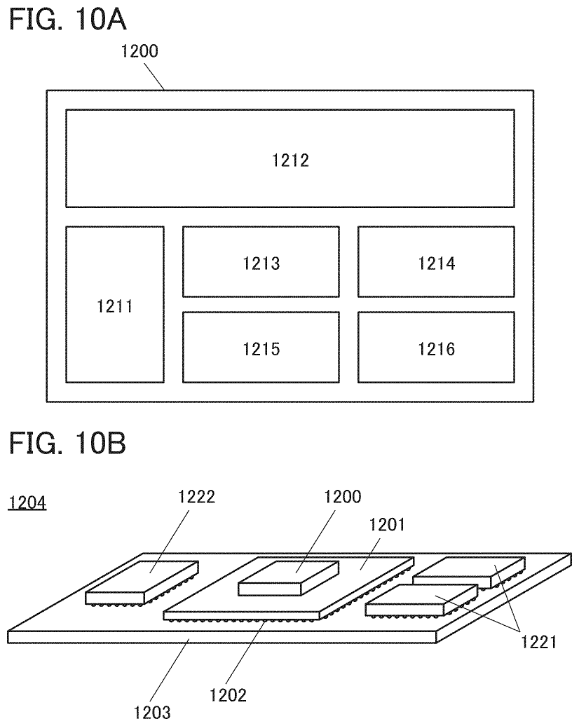

In this embodiment, an example of a chip 1200 on which the semiconductor device of the present invention is mounted is described with reference to FIG. 10. A plurality of circuits (systems) are mounted on the chip 1200. The technique for integrating a plurality of circuits (systems) on one chip is referred to as system on chip (SoC) in some cases.

As illustrated in FIG. 10(A), the chip 1200 includes a CPU (Central Processing Unit) 1211, a GPU (Graphics Processing Unit) 1212, one or more of analog arithmetic units 1213, one or more of memory controllers 1214, one or more of interfaces 1215, one or more of network circuits 1216, and the like.

A bump (not illustrated) is provided on the chip 1200, and as illustrated in FIG. 10(B), the chip 1200 is connected to a first surface of a printed circuit board (PCB) 1201. A plurality of bumps 1202 are provided on the rear side of the first surface of the PCB 1201, and the PCB 1201 is connected to a motherboard 1203.

A memory device such as a DRAM 1221 or a flash memory 1222 may be provided over the motherboard 1203. For example, the DOSRAM described in the above embodiment can be used as the DRAM 1221. For example, the NOSRAM described in the above embodiment can be used as the flash memory 1222.

The CPU 1211 preferably includes a plurality of CPU cores. Furthermore, the GPU 1212 preferably includes a plurality of GPU cores. The CPU 1211 and the GPU 1212 may each include a memory for storing data temporarily. Alternatively, a common memory for the CPU 1211 and the GPU 1212 may be provided in the chip 1200. The NOSRAM or the DOSRAM described above can be used as the memory. The GPU 1212 is suitable for parallel computation of a number of data and thus can be used for image processing or product-sum operation. When an image processing circuit or a product-sum operation circuit including an oxide semiconductor of the present invention is provided in the GPU 1212, image processing and product-sum operation can be performed with low power consumption.

In addition, since the CPU 1211 and the GPU 1212 are provided in the same chip, a wiring between the CPU 1211 and the GPU 1212 can be shortened; accordingly, the data transfer from the CPU 1211 to the GPU 1212, the data transfer between the memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an analog/digital (A/D) converter circuit and a digital/analog (D/A) converter circuit. Furthermore, the analog arithmetic unit 1213 may include the above-described product-sum operation circuit.

The memory controller 1214 includes a circuit functioning as a controller of the DRAM 1221 and a circuit functioning as the interface of the flash memory 1222.

The interface 1215 includes an interface circuit for connection with an external connection device such as a display device, a speaker, a microphone, a camera, or a controller. Examples of the controller include a mouse, a keyboard, and a game controller. As such an interface, USB (Universal Serial Bus), HDMI (registered trademark) (High-Definition Multimedia Interface), or the like can be used.

The network circuit 1216 includes a network circuit such as a LAN (Local Area Network). Furthermore, the network circuit 1216 may include a circuit for network security.

The circuits (systems) can be formed in the chip 1200 in the same manufacturing process. Therefore, even when the number of circuits needed for the chip 1200 is increased, there is no need to increase the number of steps in the manufacturing process; thus, the chip 1200 can be manufactured at low cost.

The motherboard 1203 provided with the PCB 1201 on which the chip 1200 including the GPU 1212 is mounted, the DRAM 1221, and the flash memory 1222 can be referred to as a GPU module 1204.

The GPU module 1204 includes the chip 1200 formed using the SoC technology, and thus can have a small size. Furthermore, the GPU module 1204 is excellent in image processing, and thus is suitably used in a portable electronic device such as a smartphone, a tablet terminal, a laptop PC, or a portable (mobile) game console. Furthermore, the product-sum operation circuit using the GPU 1212 can implement the arithmetic operation in a deep neural network (DNN), a convolutional neural network (CNN), a recurrent neural network (RNN), an autoencorder, a deep Boltzmann machine (DBM), a deep belief network (DBN), or the like; thus, the chip 1200 can be used as an AI chip or the GPU module 1204 can be used as an AI system module.

The structure described in this embodiment can be used in appropriate combination with any of the structures described in the other embodiments.

### Embodiment 6

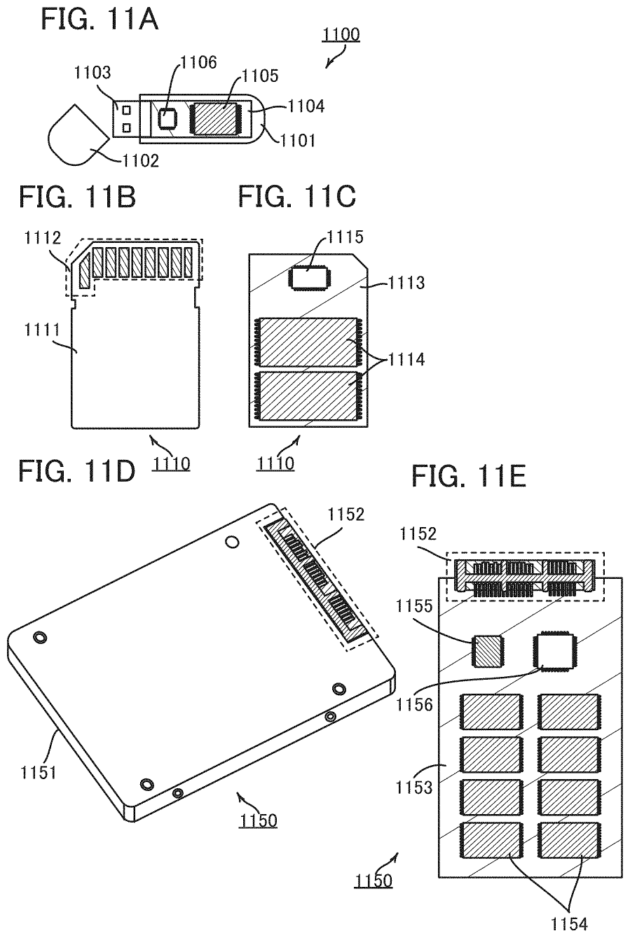

In this embodiment, application examples of the memory device using the semiconductor device described in the above embodiment are described. The semiconductor device described in the above embodiment can be applied to, for example, memory devices of a variety of electronic devices (e.g., information terminals, computers, smartphones, e-book readers, digital cameras (including video cameras), video recording/reproducing devices, and navigation systems). Here, the computers refer not only to tablet computers, notebook computers, and desktop computers, but also to large computers such as server systems. Alternatively, the semiconductor device described in the above embodiment is applied to removable memory devices such as memory cards (e.g., SD cards), USB memories, and solid state drives (SSD). FIG. 11 schematically illustrates some structural examples of removable memory devices. A packaged memory chip including the semiconductor device described in the above embodiment is used in a variety of memory devices and removable memories, for example.

FIG. 11(A) is a schematic view of a USB memory. A USB memory 1100 includes a housing 1101, a cap 1102, a USB connector 1103, and a substrate 1104. The substrate 1104 is held in the housing 1101. For example, a memory chip 1105 and a controller chip 1106 are attached to the substrate 1104. The semiconductor device described in the above embodiment can be incorporated in the memory chip 1105 or the like on the substrate 1104.

FIG. 11(B) is a schematic external view of an SD card, and FIG. 11(C) is a schematic view illustrating the internal structure of the SD card. An SD card 1110 includes a housing 1111, a connector 1112, and a substrate 1113. The substrate 1113 is held in the housing 1111. For example, a memory chip 1114 and a controller chip 1115 are attached to the substrate 1113. When the memory chip 1114 is also provided on the rear side of the substrate 1113, the capacity of the SD card 1110 can be increased. In addition, a wireless chip with a radio communication function may be provided on the substrate 1113. With such a wireless chip, data can be read from and written in the memory chip 1114 by radio communication between the host device and the SD card 1110. The semiconductor device described in the above embodiment can be incorporated in the memory chip 1114 or the like on the substrate 1113.

FIG. 11(D) is a schematic external view of an SSD, and FIG. 11(E) is a schematic view illustrating the internal structure of the SSD. An SSD 1150 includes a housing 1151, a connector 1152, and a substrate 1153. The substrate 1153 is held in the housing 1151. For example, a memory chip 1154, a memory chip 1155, and a controller chip 1156 are attached to the substrate 1153. The memory chip 1155 is a work memory for the controller chip 1156, and a DOSRAM chip may be used, for example. When the memory chip 1154 is also provided on the rear side of the substrate 1153, the capacity of the SSD 1150 can be increased. The semiconductor device described in the above embodiment can be incorporated in the memory chip 1154 or the like on the substrate 1153.

This embodiment can be implemented in an appropriate combination with any of the structures described in the other embodiments and the like.

### REFERENCE NUMERALS

100 capacitor, 110 conductor, 112 conductor, 120 conductor, 130 insulator, 150 insulator, 200 transistor, 203 conductor, 205 conductor, 205a conductor, 205b conductor, 210 insulator, 212 insulator, 214 insulator, 216 insulator, 218 conductor, 220 insulator, 222 insulator, 224 insulator, 230 oxide, 230a oxide, 230b oxide, 230c oxide, 231 region, 231a region, 231b region, 235 oxide, 235a oxide, 235b oxide, 240 conductor, 240a conductor, 240b conductor, 246 conductor, 246a conductor, 246b conductor, 250 insulator, 260 conductor, 260a conductor, 260b conductor, 273 insulator, 274 insulator, 276 insulator, 276a insulator, 276b insulator, 280 insulator, 282 insulator, 284 insulator, 300 transistor, 311 substrate, 313 semiconductor region, 314a low-resistance region, 314b low-resistance region, 315 insulator, 316 conductor, 320 insulator, 322 insulator, 324 insulator, 326 insulator, 328 conductor, 330 conductor, 350 insulator, 352 insulator, 354 insulator, 356 conductor, 400 transistor, 405 conductor, 405a conductor, 405b conductor, 430c oxide, 431a oxide, 431b oxide, 432a oxide, 432b oxide, 440 conductor, 440a conductor, 440b conductor, 446 conductor, 446a conductor, 446b conductor, 450 insulator, 460 conductor, 460a conductor, 460b conductor

1.-7. (canceled)

8. A transistor comprising:
a conductor;
an oxide semiconductor; and
an insulator between the conductor and the oxide semiconductor,
wherein the oxide semiconductor includes indium, zinc, and a metal element M, and
wherein M is one or more of metal elements selected from cerium, tungsten, and molybdenum.

9. The transistor according to claim 8,
wherein the metal element M is greater than or equal to 0.01 atomic % and less than or equal to 1.0 atomic % of metal atoms included in the oxide semiconductor.

10. The transistor according to claim 8,
wherein the metal element M is cerium.

11. The transistor according to claim 8,
wherein the oxide semiconductor includes a CAAC-OS.

12. The transistor according to claim 8,
wherein the oxide semiconductor includes an nc-OS.

13. A transistor comprising:
a conductor;
an oxide semiconductor; and
an insulator between the conductor and the oxide semiconductor,
wherein the oxide semiconductor includes indium, zinc, gallium, and a metal element M, and
wherein M is one or more of metal elements selected from cerium, tungsten, and molybdenum.

14. The transistor according to claim 13,
wherein the metal element M is greater than or equal to 0.01 atomic % and less than or equal to 1.0 atomic % of metal atoms included in the oxide semiconductor.

15. The transistor according to claim 13,
wherein the metal element M is cerium.

16. The transistor according to claim 13,
wherein the oxide semiconductor includes a CAAC-OS.

17. The transistor according to claim 13,
wherein the oxide semiconductor includes an nc-OS.

18. A transistor comprising a first oxide, a second oxide, a third oxide, a first conductor, a second conductor, a third conductor, and an insulator,
wherein the first oxide includes a first region, a second region, and a third region,
wherein the first region includes a region overlapping with the first conductor with the insulator therebetween,
wherein the second region overlaps with the second conductor with the second oxide therebetween,
wherein the third region overlaps with the third conductor with the third oxide therebetween, and
wherein the second oxide and the third oxide have higher cerium contents than the first oxide.

19. The transistor according to claim 18,
wherein the oxide semiconductor includes a CAAC-OS.

20. The transistor according to claim 18,
wherein the oxide semiconductor includes an nc-OS.
